(19) United States
(12) Patent Application Publication
(10) Pub. No.: US 2017/0280545 A1
(43) Pub. Date: Sep. 28, 2017

(54) EXTREME ULTRAVIOLET LIGHT GENERATING SYSTEM, EXTREME ULTRAVIOLET LIGHT GENERATING METHOD, AND THOMSON SCATTERING MEASUREMENT SYSTEM

(71) Applicants: KYUSHU UNIVERSITY, NATIONAL UNIVERSITY CORPORATION, Fukuoka (JP); GIGAPHOTON INC., Tochigi (JP)

(72) Inventors: Kentaro TOMITA, Fukuoka (JP); Kiichiro UCHINO, Fukuoka (JP); Tatsuya YANAGIDA, Tochigi (JP); Osamu WAKABAYASHI, Tochigi (JP); Hiroaki TOMURO, Tochigi (JP)

(73) Assignees: KYUSHU UNIVERSITY, NATIONAL UNIVERSITY CORPORATION, Fukuoka (JP); GIGAPHOTON INC., Tochigi (JP)

(21) Appl. No.: 15/622,139

(22) Filed: Jun. 14, 2017

Related U.S. Application Data
(63) Continuation of application No. PCT/JP2015/051874, filed on Jan. 23, 2015.

(51) Int. Cl. H05G 2/00; G01J 3/44

(52) U.S. Cl. CPC H05G 2/008; G01J 3/4412; G03F 7/70033

(57) ABSTRACT

An extreme ultraviolet light generating system may include: a chamber; a target feeding unit configured to feed a target into the chamber; a drive laser unit configured to irradiate the target with a drive pulsed laser light beam to generate a plasma to thereby generate extreme ultraviolet light; a probe laser unit configured to irradiate the plasma with a probe pulsed laser light beam to thereby generate Thomson scattered light; a spectrometer configured to measure a spectrum waveform of an ionic term in the Thomson scattered light; and a wavelength filter disposed upstream of the spectrometer, and configured to suppress light with a predetermined wavelength from entering the spectrometer. The light with the predetermined wavelength may be part of light containing the Thomson scattered light, and the predetermined wavelength may be substantially same as a wavelength of the probe pulsed laser light beam.

### CROSS REFERENCE TO RELATED APPLICATIONS

The present application is a continuation application of International Application No. PCT/JP2015/051874 filed on Jan. 23, 2015. The content of the application is incorporated herein by reference in its entirety.

### BACKGROUND

### 1. Technical Field

The present disclosure relates to an extreme ultraviolet light generating system to generate extreme ultraviolet (EUV) light and an extreme ultraviolet light generating method, and to a Thomson scattering measurement system.

### 2. Related Art

In recent years, miniaturization of a transfer pattern of an optical lithography in a semiconductor process is drastically progressing with the development in fining of the semiconductor process. In the next generation, microfabrication on the order of 70 nm to 45 nm, and further microfabrication on the order of 32 nm or less are bound to be required. To meet such requirement for the microfabrication on the order of, for example, 32 nm or less, development is anticipated of an exposure apparatus that includes a combination of a reduced projection reflective optics and an extreme ultraviolet light generating apparatus that generates extreme ultraviolet (EUV) light with a wavelength of about 13 nm. For example, reference is made in U.S. Patent Application Publication No. 2013/0148203, U.S. Pat. No. 8,181,511, U.S. Pat. No. 8,674,304, and International Publication No. WO 2005/069451.

As the EUV light generating apparatus, there have been proposed three kinds of apparatuses, a laser produced plasma (LPP) apparatus using a plasma generated by irradiation of a target substance with laser light, a discharge produced plasma (DPP) apparatus using a plasma generated by electric discharge, and a synchrotron radiation (SR) apparatus using orbital radiation light.

### SUMMARY

An extreme ultraviolet light generating system according to one aspect of the present disclosure may include a chamber, a target feeding unit, a drive laser unit, a probe laser unit, a spectrometer, and a wavelength filter. The target feeding unit may be configured to feed a target into the chamber. The drive laser unit may be configured to irradiate the target with a drive pulsed laser light beam to generate a plasma to thereby generate extreme ultraviolet light. The probe laser unit may be configured to irradiate the plasma with a probe pulsed laser light beam to thereby generate Thomson scattered light. The spectrometer may be configured to measure a spectrum waveform of an ionic term in the Thomson scattered light. The wavelength filter may be disposed upstream of the spectrometer, and may be configured to suppress light with a predetermined wavelength from entering the spectrometer. The light with the predetermined wavelength may be part of light containing the Thomson scattered light, and the predetermined wavelength may be substantially same as a wavelength of the probe pulsed laser light beam.

An extreme ultraviolet light generating method according to one aspect of the present disclosure may include: feeding a target into a chamber; irradiating the target with a drive pulsed laser light beam to generate plasma to thereby generate extreme ultraviolet light; irradiating the plasma with a probe pulsed laser light beam to thereby generate Thomson scattered light; measuring, by a spectrometer, a spectrum waveform of an ionic term in the Thomson scattered light; and suppressing, upstream of the spectrometer, light with a predetermined wavelength from entering the spectrometer. The light with the predetermined wavelength may be part of light containing the Thomson scattered light, and the predetermined wavelength may be substantially same as a wavelength of the probe pulsed laser light beam.

A Thomson scattering measurement system according to one aspect of the present disclosure may include: a probe laser unit, a spectrometer, and a wavelength filter. The probe laser unit may be configured to irradiate a plasma with a probe pulsed laser light beam to thereby generate Thomson scattered light. The spectrometer may be configured to measure a spectrum waveform of an ionic term in the Thomson scattered light. The wavelength filter may be disposed upstream of the spectrometer, and may be configured to suppress light with a predetermined wavelength from entering the spectrometer. The light with the predetermined wavelength may be part of light containing the Thomson scattered light, and the predetermined wavelength may be substantially same as a wavelength of the probe pulsed laser light beam.

### BRIEF DESCRIPTION OF THE DRAWINGS

Some example embodiments of the present disclosure are described below as mere examples with reference to the accompanying drawings.

FIG. 1 schematically illustrates a configuration example of an exemplary LPP EUV light generating system.

FIG. 2 schematically illustrates a configuration example of a Thomson scattering measurement system applied to the EUV light generating system.

FIG. 3 schematically illustrates an example of a spectrum waveform of Thomson scattered light when a scattering parameter α satisfies α>1.

FIG. 4 schematically illustrates an example of the spectrum waveform when the scattering parameter αsatisfies α<<1.

FIG. 5 schematically illustrates an example of a spectrum waveform of stray light of a probe pulsed laser light beam and an ionic term in Thomson scattered light.

FIG. 6 schematically illustrates a configuration example of a Thomson scattering measurement system according to a first embodiment applied to an EUV light generating system.

FIG. 7 schematically illustrates a configuration example of a blocking member.

FIG. 8 schematically illustrates a configuration example of a drive laser unit according to the first embodiment.

FIG. 9 schematically illustrates an example of an intensity distribution of a spectrum measured by an ICCD camera when light generated from a plasma enters a wavelength filter.

FIG. 10 schematically illustrates an example of a spectrum waveform measured in a case in which the blocking member is removed to cause Rayleigh scattered light of a probe pulsed laser light beam to enter a spectrum measurement unit.

FIG. 11 is a timing chart illustrating an example of control timings by an EUV light generation controller.

FIG. 12 schematically illustrates states until a target is turned into a plasma to generate EUV light.

FIG. 13 schematically illustrates an image in an EUV light emission state.

FIG. 14 schematically illustrates a spectrum image of an ionic term in Thomson scattered light.

FIG. 15 schematically illustrates a spectrum waveform at each of positions P11, P12, and P13 in FIG. 14.

FIG. 16 schematically illustrates an example of a spectrometer having enhanced resolution.

FIG. 17 schematically illustrates an example of a spectrum waveform of an ionic term measurable by the spectrometer illustrated in FIG. 16.

FIG. 18 schematically illustrates a configuration example of an EUV light generating system including a Thomson scattering measurement system.

FIG. 19 schematically illustrates a configuration example of a drive laser unit in the EUV light generating system illustrated in FIG. 18.

FIG. 20 is a timing chart illustrating an example of control timings the EUV light generation controller.

FIG. 21 is a main flow chart schematically illustrating an example of a flow of control for setting of a condition parameter for exposure with use of the Thomson scattering measurement system in the EUV light generating system illustrated in FIG. 18.

FIG. 22 is a sub-flow chart illustrating details of a process in step S112 of the main flow chart illustrated in FIG. 21.

FIG. 23 schematically illustrates an example of an initial condition parameter.

FIG. 24 is a sub-flow chart illustrating details of a process in step S117 of the main flow chart illustrated in FIG. 21.

FIG. 25 schematically illustrates an example of data of a test result.

FIG. 26 is a sub-flow chart illustrating details of a process in step S122 of the main flow chart illustrated in FIG. 21.

FIG. 27 is a sub-flow chart illustrating details of a process in step S124 of the main flow chart illustrated in FIG. 21.

FIG. 28 schematically illustrates an example of rewritten contents of the condition parameter.

FIG. 29 schematically illustrates an example of an embodiment of a target feeding unit that allows for adjustment of a target diameter.

FIG. 30 schematically illustrates an example of an embodiment of a laser unit that allows for control of a pulse width and pulse energy.

FIG. 31 schematically illustrates a modification example of a direction where a probe pulsed laser light beam enters.

FIG. 32 schematically illustrates a configuration example of an ICCD.

FIG. 33 schematically illustrates an example of operation of an image intensifier.

FIG. 34 illustrates an example of a hardware environment of a controller.

### DETAILED DESCRIPTION

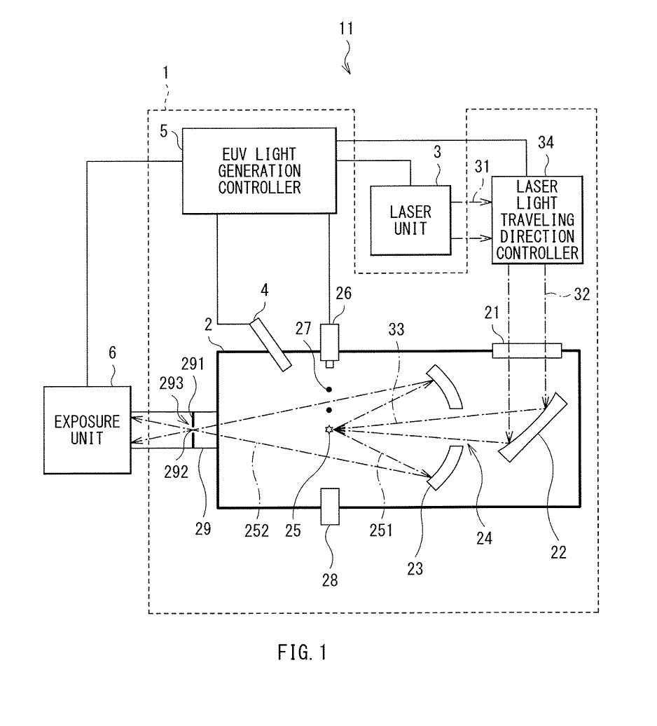

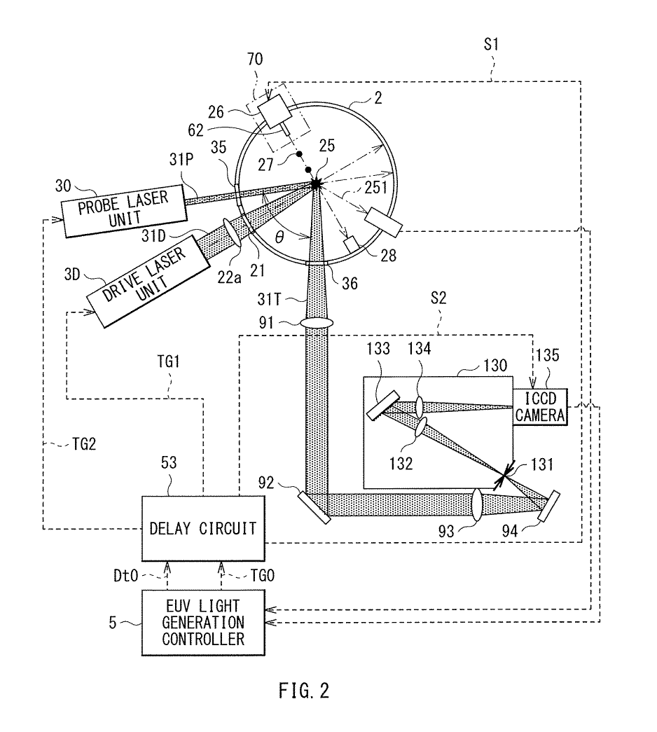

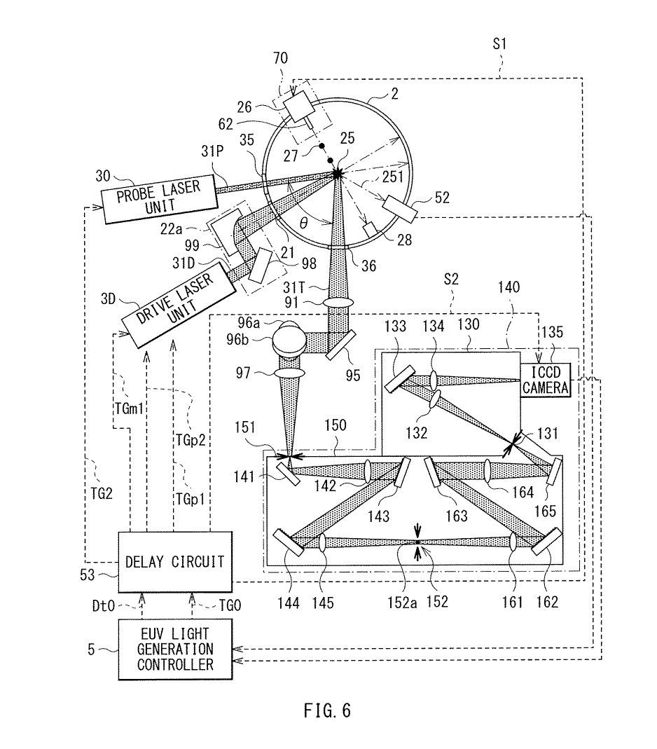

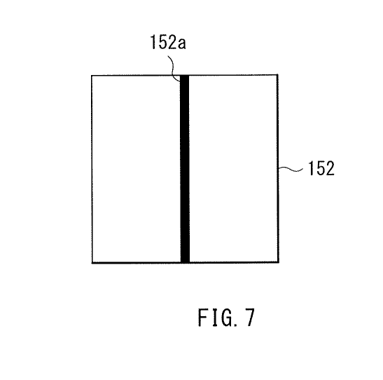

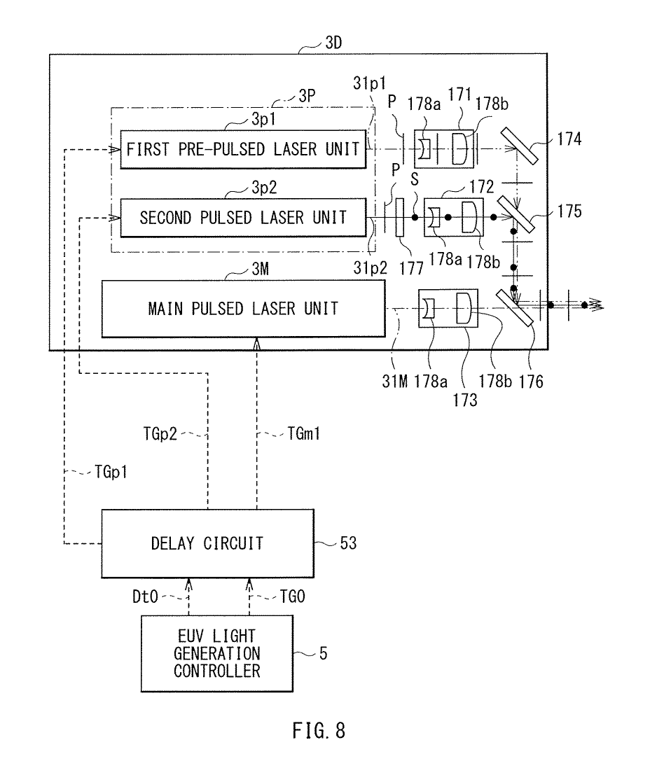

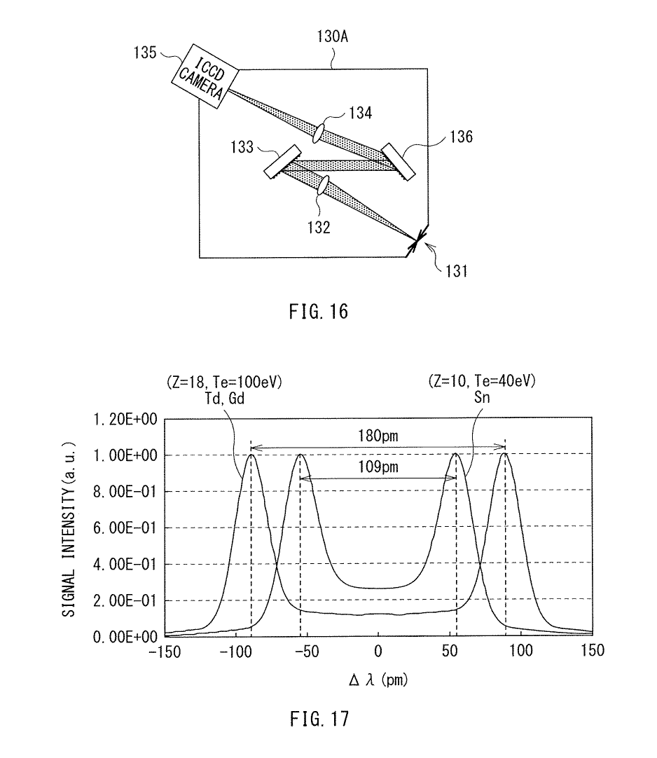

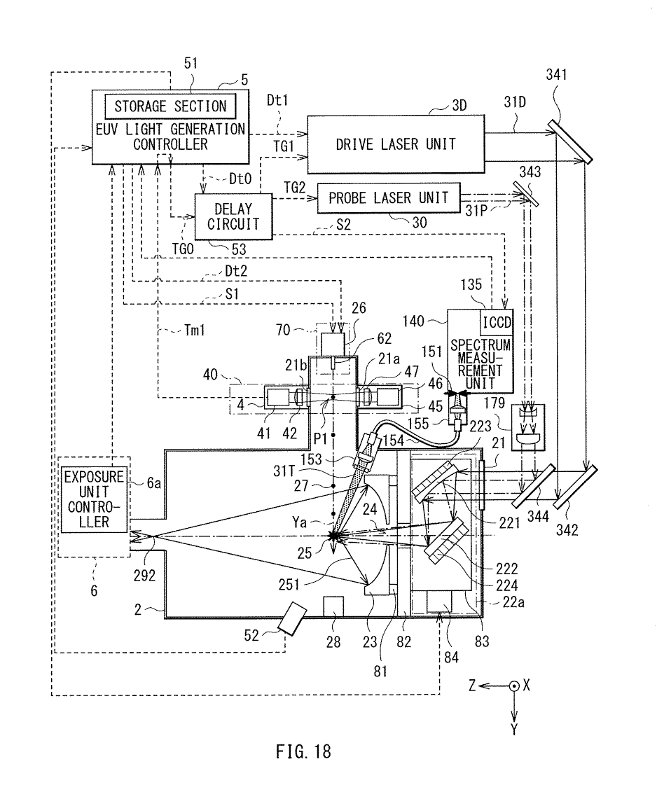

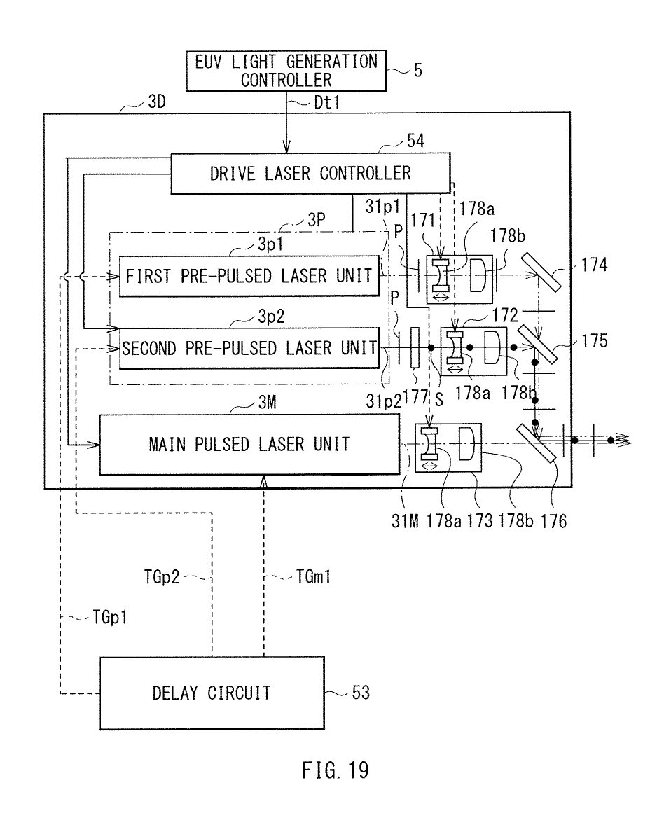

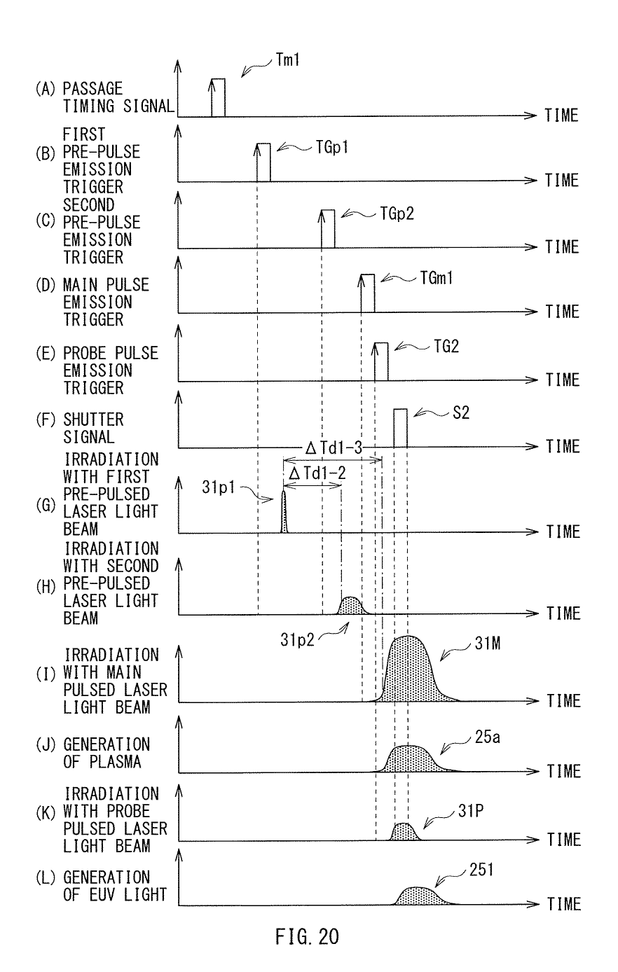

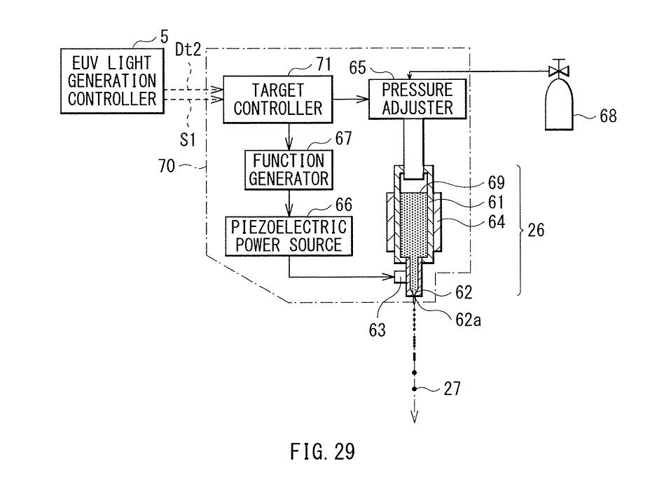

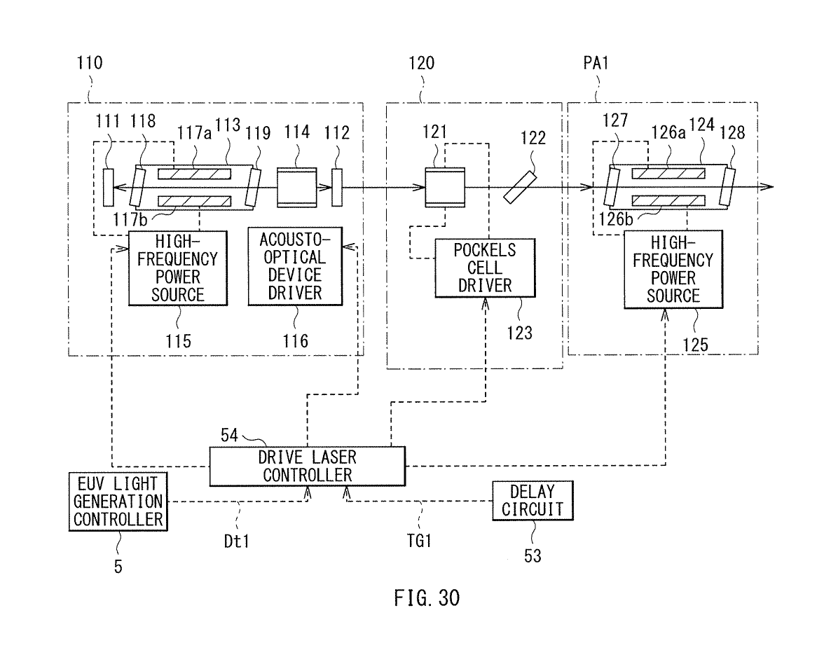

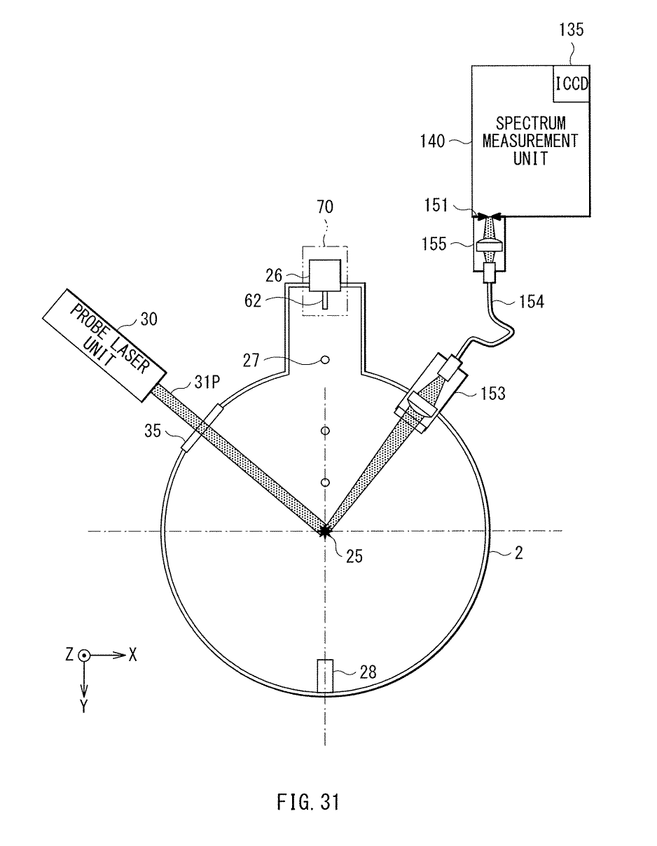

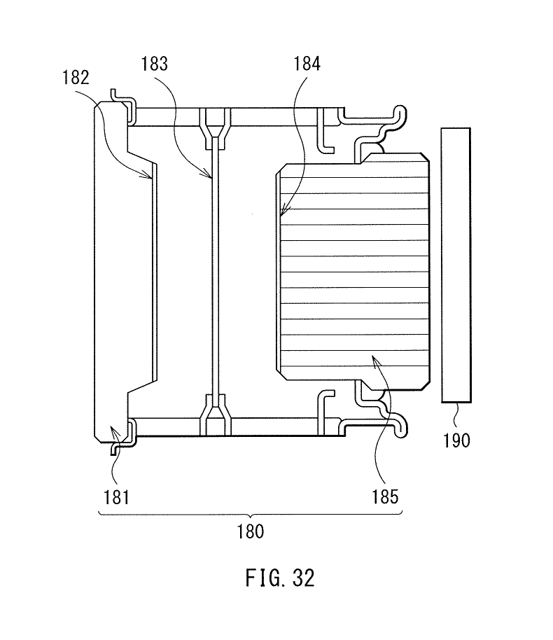

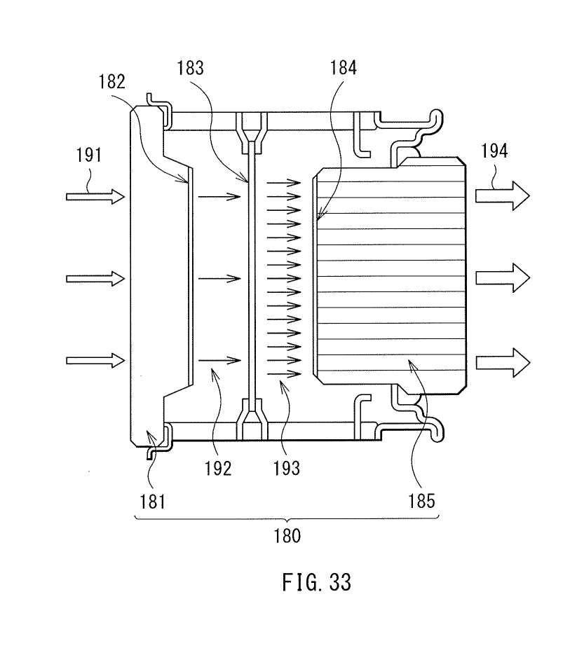

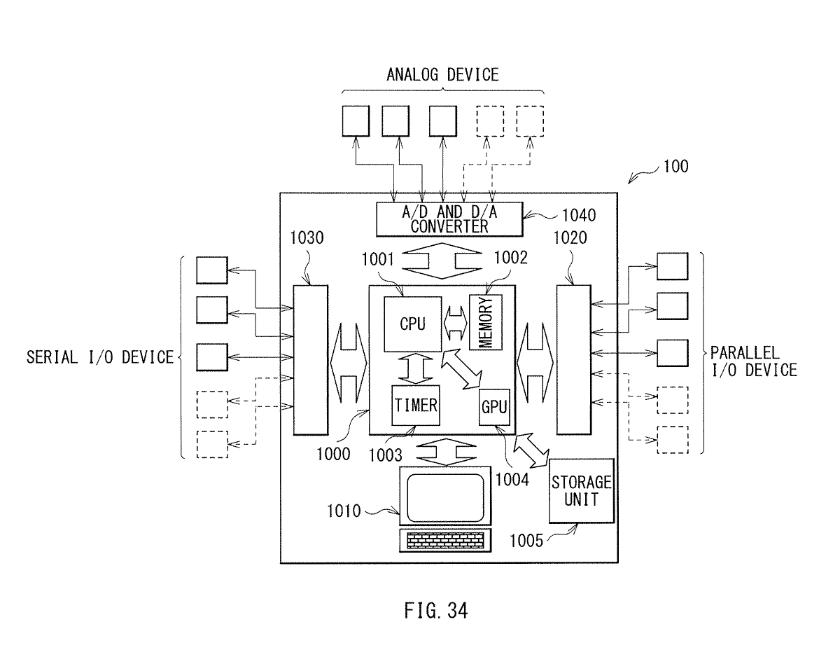

### <Contents>

[1. Overview]
[2. General Description of EUV Light Generating System] (FIG. 1)
   2.1 Configuration
   2.2 Operation
[3. Thomson Scattering Measurement System]
   3.1 Configuration (FIG. 2)
   3.2 Operation
   3.3 Spectrum Waveform of Thomson Scattered Light
   3.4 Issues
[4. First Embodiment] (Thomson Scattering Measurement System Including Wavelength Filter)
   4.1 Configuration
      4.1.1 Entire Configuration of System (FIGS. 6 and 7)
      4.1.2 Configuration of Drive laser Unit (FIG. 8)
   4.2 Operation
      4.2.1 Operation of Entire System
      4.2.2 Control Timings by EUV Light Generation Controller
   4.3 Workings
   4.4 Modification Examples (FIG. 16)
[5. Second Embodiment] (EUV Light Generating System Including Thomson Scattering Measurement System)
   5.1 Configuration
      5.1.1 Entire Configuration of System (FIG. 18)
      5.1.2 Configuration of Drive laser Unit (FIG. 19)
   5.2 Operation
   5.3 Workings
   5.4 Modification Examples
[6. Other Embodiments]
   6.1 Embodiment of Target Feeding Unit Allowing for Control of Target Diameter (FIG. 29)
      6.1.1 Configuration
      6.1.2 Operation
   6.2 Embodiment of Laser Unit Allowing for Control of Pulse Width (FIG. 30)
      6.2.1 Configuration
      6.2.2 Operation
   6.3 Embodiment of Thomson Scattering Measurement System where Probe Pulsed Laser Light Beam Enters Perpendicularly to Drive Pulsed Laser Light Beam (FIG. 31)
   6.4 Embodiment of ICCD (FIGS. 32 and 33)
[7. Hardware Environment of Controller] (FIG. 34)
[8. Et Cetera]

In the following, some example embodiments of the present disclosure are described in detail with reference to the drawings. Example embodiments described below each illustrate one example of the present disclosure and are not intended to limit the contents of the present disclosure. Further, all of the configurations and operations described in each example embodiment are not necessarily essential for the configurations and operations of the present disclosure. Note that like components are denoted by like reference numerals, and redundant description thereof is omitted.

### 1. Overview

The present disclosure relates to an extreme ultraviolet (EUV) light generating system configured to irradiate a target with pulsed laser light to turn a target into a plasma to thereby generate EUV light, and an EUV light generating method. Moreover, the present disclosure relates to a Thomson scattering measurement system configured to measure Thomson scattered light of the generated plasma.

### 2. General Description of EUV Light Generating System

2.1 Configuration

FIG. 1 schematically illustrates a configuration of an exemplary laser produced plasma (LPP) EUV light generating system. An EUV light generating apparatus 1 may be used together with one or more laser units 3. In example embodiments disclosed in the present application, a system including the EUV light generating apparatus 1 and the laser unit 3 is referred to as an EUV light generating system 11. As illustrated in FIG. 1 and as described in detail below, the EUV light generating apparatus 1 may include a chamber 2 and, for example, a target feeder 26 serving as a target feeding unit. The chamber 2 may be sealable. The target feeder 26 may be so attached as to penetrate a wall of the chamber 2, for example. A material of a target substance to be supplied from the target feeder 26 may be tin, terbium, gadolinium, lithium, xenon, or any combination of two or more thereof without limitation.

The wall of the chamber 2 may be provided with one or more through holes. A window 21 may be provided at the through hole. Pulsed laser light 32 outputted from the laser unit 3 may pass through the window 21. An EUV light concentrating mirror 23 including, for example, a spheroidal reflection surface may be provided inside the chamber 2. The EUV light concentrating mirror 23 may include a first focal point and a second focal point. A surface of the EUV light concentrating mirror 23 may be provided with a multilayer reflection film in which, for example, molybdenum and silicon are alternately stacked. For example, the EUV light concentrating mirror 23 may be preferably disposed so that the first focal point is located in a plasma generation region 25 or in the vicinity of the plasma generation region 25, and that the second focal point is located at an intermediate focus point (IF) 292. The intermediate focus point 292 may be a desired light concentration position defined by specifications of an exposure unit 6. The EUV light concentrating mirror 23 may be provided with a through hole 24 provided at a center part of the EUV light concentrating mirror 23 and through which pulsed laser light 33 may pass.

The EUV light generating apparatus 1 may include an EUV light generation controller 5. The EUV light generation controller 5 may include a target sensor 4, etc. The target sensor 4 may detect one or more of presence, trajectory, position, and speed of a target 27. The target sensor 4 may include an imaging function.

The EUV light generating apparatus 1 may further include a connection section 29 that allows the inside of the chamber 2 to be in communication with the inside of the exposure unit 6. A wall 291 provided with an aperture 293 may be provided inside the connection section 29. The wall 291 may be disposed so that the aperture 293 is located at the second focal point of the EUV light concentrating mirror 23.

The EUV light generating apparatus 1 may further include a laser light traveling direction controller 34, a laser light concentrating mirror 22, a target collector 28, etc. The target collector 28 may collect the target 27. The laser light traveling direction controller 34 may include, in order to control a traveling direction of laser light, an optical device that defines the traveling direction of the laser light and an actuator that adjusts position, attitude, etc., of the optical device.

### 2.2 Operation

With reference to FIG. 1, pulsed laser light 31 outputted from the laser unit 3 may travel through the laser light traveling direction controller 34. The pulsed laser light 31 that has passed through the laser light traveling direction controller 34 may enter, as the pulsed laser light 32, the chamber 2 after passing through the window 21. The pulsed laser light 32 may travel inside the chamber 2 along one or more laser light paths, and then may be reflected by the laser light concentrating mirror The pulsed laser light 32 reflected by the laser light concentrating mirror 22 may be applied, as the pulsed laser light 33, to one or more targets 27.

The target feeder 26 may be adapted to output the target 27 to the plasma generation region 25 inside the chamber 2. The target 27 may be irradiated with one or more pulses included in the pulsed laser light 33. The target 27 irradiated with the pulsed laser light may be turned into a plasma, and EUV light 251 may be radiated together with radiation light from the plasma. The EUV light 251 may be reflected and concentrated by the EUV light concentrating mirror 23. EUV light 252 reflected by the EUV light concentrating mirror 23 may travel through the intermediate focus point 292. The EUV light 252 having travelled through the intermediate focus point 292 may be outputted to the exposure unit 6. Note that a plurality of pulses included in the pulsed laser light 33 may be applied to one target 27.

The EUV light generation controller 5 may be adapted to manage a control of the EUV light generating system 11 as a whole. The EUV light generation controller 5 may be adapted to process, for example, data of an image of the target 27 taken by the target sensor 4. For example, the EUV light generation controller 5 may be adapted to control one or both of an output timing of the target 27 and an output direction of the target 27.

For example, the EUV light generation controller 5 may be adapted to control one or more of an oscillation timing of the laser unit 3, the traveling direction of the pulsed laser light 32, and a concentration position of the pulsed laser light 33. The above-described various controls are illustrative, and any other control may be added as necessary.

### 3. Thomson Scattering Measurement System

(3.1 Configuration)

FIG. 2 schematically illustrates a configuration example of a Thomson scattering measurement system applied to, for example, the EUV light generating system 11 illustrated in FIG. 1. Note that substantially same components as the components in FIG. 1 are denoted by same reference numerals, and redundant description thereof is omitted.

The Thomson scattering measurement system may include the chamber 2, the EUV light generation controller 5, a drive laser unit 3D, a probe laser unit 30, a laser concentrating optical system 22a, and a delay circuit 53. The Thomson scattering measurement system may further include a collimator lens 91, a high reflection mirror 92, a light concentrating lens 93, a high reflection mirror 94, and a spectrometer 130.

The chamber 2 may include the window 21, a window 35, a window 36, the target collector 28, an energy sensor 52, and a target feeding unit 70.

The target feeding unit 70 may include the target feeder 26 provided with a nozzle 62. The target feeding unit 70 may be attached to the chamber 2 so as to supply the target 27 to the plasma generation region 25. The target feeder 26 may store a target material such as tin. The target feeder 26 may heat the target material, by an unillustrated heater, to a predetermined temperature equal to or higher than the melting point of the target material. For example, in a case in which the target material is tin of which the melting point is 232° C., the target material may be heated to a temperature of 280° C., for example.

The target feeding unit 70 may be adapted to generate the target 27 in a droplet form on demand and output the target 27 from the nozzle 62 in response to input of a target output signal S1 from the EUV light generation controller 5. The target feeding unit 70 may generate the target 27 by application of a high-voltage pulse between an unillustrated extraction electrode and the nozzle 62 as with ink jet-technology, for example.

The energy sensor 52 may detect energy of the EUV light 251. The energy sensor 52 may include an unillustrated filter and an unillustrated photodiode through which the EUV light 251 passes, and may be attached to the chamber 2 so as to direct a detection direction thereof toward the plasma generation region 25.

The target collector 28 may be disposed on an extended line of a trajectory of the target 27 supplied from the target feeding unit 70 to collect, for example, the target 27 that has not been turned into a plasma.

The window 21 may be fixed to the chamber 2 by sealing in an optical path of a drive pulsed laser light beam 31D. The window 35 may be fixed to the chamber 2 by sealing in an optical path of a probe pulsed laser light beam 31P. The window 36 may be fixed to the chamber 2 by sealing in an optical path of Thomson scattered light 31T.

The drive laser unit 3D may he a laser unit that turns the target 27 into a plasma by heating to output the drive pulsed laser light beam 31D used for generation of the EUV light 251. The drive laser unit 3D may be a CO₂ laser unit that outputs pulsed laser light with a wavelength of 10.6 μm. The drive laser unit 3D and the laser concentrating optical system 22a may be disposed so as to concentrate the drive pulsed laser light beam 31D onto the target 27 supplied to the plasma generation region 25 via the laser concentrating optical system 22a and the window 21.

The probe laser unit 30 may be a laser unit that outputs the probe pulsed laser light beam 31P used for measurement of the Thomson scattered light 31T from the plasma generated in the plasma generation region 25. The probe laser unit 30 may be, for example, a laser unit that generates a second harmonic of a YAG laser. The YAG laser may oscillate in a single longitudinal mode. The second harmonic of the YAG layer may have a wavelength of 532.0 nm. The probe laser unit 30 may be so disposed as to irradiate the plasma generated in the plasma generation region 25 with the probe pulsed laser light beam 31P via the window 35.

The spectrometer 130 may measure a spectrum waveform of an ionic term in the Thomson scattered light 31T. The spectrometer 130 may include an entrance slit 131, a collimator optical system 132, a grating 133, a light concentrating optical system 134, and an intensified charge-coupled device (ICCD) camera 135. The collimator optical system 132 and the grating 133 may be so disposed as to allow light having passed through the entrance slit 131 to be collimated by the collimator optical system 132 and then to enter the grating 133 at an entrance angle α1. The light concentrating optical system 134 may be so disposed as to allow light diffracted at a diffraction angle β1 by the grating 133 to be concentrated onto a light reception surface of the ICCD camera 135 to thereby measure an diffraction image of the entrance slit 131 on the light reception surface.

The collimator lens 91 may be so disposed as to collimate the Thomson scattered light 31T having entered the collimator lens 91 via the window 36.

The high reflection mirror 92 may be so disposed as to allow the Thomson scattered light 31T collimated by the collimator lens 91 to enter the light concentrating lens 93.

The light concentrating lens 93 may be so disposed as to allow the entrance slit 131 to be illuminated with the Thomson scattered light 31T via the high reflection mirror 94.

The delay circuit 53 may be coupled to the target feeding unit 70 so as to allow for outputting of the target output signal S1 to the target feeding unit 70. The delay circuit 53 may be further coupled to the drive laser unit 3D so as to allow for outputting of a drive pulse emission trigger TG1 to the drive laser unit 3D. The delay circuit 53 may be further coupled to the probe laser unit 30 so as to allow for outputting of a probe pulse emission trigger TG2 to the probe laser unit 30. The delay circuit 53 may be further coupled to the ICCD camera 135 so as to allow for outputting of a shutter signal S2 to the ICCD camera 135.

The EUV light generation controller 5 may be coupled to the delay circuit 53 and the ICCD camera 135.

### (3.2 Operation)

The EUV light generation controller 5 may output delay data Dt0 to the delay circuit 53. The delay data Dt0 may indicate a delay time of each of the target output signal S1, the drive pulse emission trigger TG1, the probe pulse emission trigger TG2, and the shutter signal S2. The EUV light generation controller 5 may also output a trigger signal TG0 to the delay circuit 53 so as to allow each of the signals mentioned above to be generated at a predetermined delay time.

First, when the target output signal S1 is inputted to the target feeding unit 70, the target 27 in a droplet form may be outputted from the nozzle 62 of the target feeding unit 70. When the drive pulse emission trigger TG1 is inputted to the drive laser unit 3D, the drive laser unit 3D may output the drive pulsed laser light beam 31D. The target 27 having reached the plasma generation region 25 may be irradiated with the drive pulsed laser light beam 31D via the laser concentrating optical system 22a. This may cause the target 27 to be turned into a plasma to thereby generate the EUV light 251. The energy sensor 52 may detect energy of the EUV light 251 and output a detection value of the detected energy to the EUV light generation controller 5.

In contrast, when the probe pulse emission trigger TG2 is inputted to the probe laser unit 30, the probe laser unit 30 may output the probe pulsed laser light beam 31P to irradiate the plasma with the probe pulsed laser light beam 31P. The Thomson scattered light 31T of the probe pulsed laser light beam 31P from the plasma may be transmitted by the collimator lens 91, the high reflection mirror 92, the light concentrating lens 93, and the high reflection mirror 94 to illuminate the entrance slit 131 of the spectrometer 130. The Thomson scattered light 31T having passed through the entrance slit 131 may be collimated by the collimator optical system 132 to enter the grating 133, and thereafter the grating 133 may generate diffracted light. The diffracted light by the grating 133 may be concentrated onto the light reception surface of the ICCD camera 135 by the light concentrating optical system 134. This may cause a diffraction image of the entrance slit 131 to be formed on the light reception surface of the ICCD camera 135.

When the shutter signal S2 is inputted to the ICCD camera 135, the ICCD camera 135 may be turned to a shutter open state at an input timing of the shutter signal S2 only for a time equal to a pulse width of the shutter signal S2, and may measure an image during the time. Since the diffracted light varies in diffraction angle depending on a wavelength of that light, a spectrum waveform of an ionic term in the Thomson scattered light 31T during a time when the shutter signal S2 is inputted may be measured on the light reception surface of the ICCD camera 135. The ICCD camera 135 may output a result of such measurement as image data to the EUV light generation controller 5.

### (3.3 Spectrum Waveform of Thomson Scattered Light)

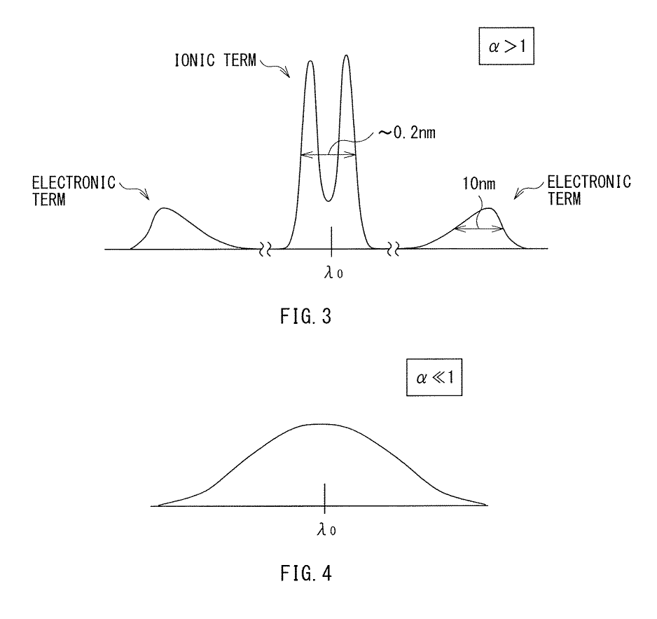

With reference to FIGS. 3 and 4, description is given of the spectrum waveform of the Thomson scattered light 31T. FIG. 3 schematically illustrates an example of the spectrum waveform of the Thomson scattered light 31T when a scattering parameter α to be described later satisfies α>1. FIG. 4 schematically illustrates an example of the spectrum waveform when the scattering parameter α satisifes α<<1. In FIGS. 3 and 4, a horizontal axis may indicate a wavelength difference Δλ from a wavelength λ₀ of the probe pulsed laser light beam 31P defined as a center wavelength, and a vertical axis may indicate signal intensity.

The scattering parameter α of the Thomson scattered light 31T may be given by the following expression. In the following expression, λ_{D}, k, λ₀, θ, nₑ, Tₑ, ε₀, and e may indicate a Debye length, a wave number, the wavelength of the probe pulsed laser light beam 31P, a scattering angle, electron density, electron temperature, a dielectric constant of vacuum, and an elementary charge, respectively.

$$α = \frac{1}{k {λ}_{D}} = \frac{{λ}_{0}}{4 π sin ( θ \text{/} 2 )} {( \frac{{n}_{e} {e}^{2}}{{ɛ}_{0} {eT}_{e}} )}^{1 / 2} \qquad [ Math . 1 ]$$

Here, scattering when the scattering parameter α is greater than 1 (α>1) is referred to as collective scattering, which means scattering by collective motion of an electron group. Scattering when the scattering parameter α is much less than 1 (α<<1) is referred to as incoherent scattering, which means that a scattering cross section by a plasma is determined only by thermal motion of individual electrons.

The spectrum waveform of the Thomson scattered light 31T from the plasma that generates the EUV light 251 may be a spectrum waveform by the collective scattering. In the incoherent scattering, only a spectrum waveform of an electronic term may be observed, as illustrated in FIG. 4, whereas in the collective scattering, a spectrum waveform of an ionic term and a spectrum waveform of an electronic term may be observed, as illustrated in FIG. 3. In the collective scattering, the spectrum of the ionic term and the spectrum of the electronic term may be respectively observed on short wavelength side and long wavelength side symmetrically with respect to the wavelength λ₀ of the probe pulsed laser light beam 31P.

### (Method of Determining Plasma Parameter)

The spectrum waveform of the ionic term having a wavelength close to the wavelength λ₀ of the probe pulsed laser light beam 31P may be observed with strong signal intensity. Accordingly, measuring the ionic term may make it possible to estimate a plasma parameter with high accuracy. Measuring the spectrum waveform of the ionic term may make it possible to calculate an ionic valence Z, the electron density nₑ, the electron temperature Tₑ, and ion temperature Tᵢ from a shape of the spectrum waveform of the ionic term, a peak wavelength of the ionic term, and the signal intensity. Values of Z and Tₑ may be determined on the basis of a value of Z·Te, separately from theoretical table values from a collisional-radiative (CR) model.

The spectrum waveform of the ionic term may be characterized by a parameter β represented by the following expression. For example, a ratio R of a central depression and a peak value of the spectrum waveform of the ionic term in FIG. 3 may be changed to R=2, 3, 5, and 10 respectively corresponding to β=1.5, 2, 2.5. and 3. for example. A specific spectrum function S(k, Δλ) of the Thomson scattered light 31T is described in detail in Chapter 5, Section 5.2 or 5.3 of D. H. Froula, S. H. Glenzer, N. C. Luhmann, Jr., and J. Sheffield: Plasma Scattering of Electromagnetic Radiation (Academic Press, USA, 2011) 2nd ed.

$$β = \sqrt{\frac{{α}^{2}}{1 + {α}^{2}}} \frac{{ZT}_{e}}{{T}_{i}} \qquad [ Math . 2 ]$$

Note that in the foregoing reference, the spectrum function is indicated not as a function of the wavelength difference Δλ but as a function of a frequency difference Δω (simply “ω” in the reference). Conversion from Δω to Δλ may be made by the following expression.

Δλ={λ₀²/(2πc)}Δω

Next, a peak wavelength Δλₚ of the ionic term may be given by the following expression. The peak wavelength Δλₚ in the following expression may be a shift amount from the wavelength λ₀ of the probe pulsed laser light beam 31P. In the following expression, κ may be a Boltzmann constant, and Mᵢ may be ion mass.

$$Δ {λ}_{p} = \frac{{λ}_{0}^{2} k}{2 π c} \sqrt{\frac{κ ( {ZT}_{e} + 3 {T}_{i} )}{{M}_{i}}} \qquad [ Math . 3 ]$$

An absolute value of the electron density nₑ may be derived by calibrating total intensity I_{T} of an ionic term in Thomson scattering by intensity I_{R} of Rayleigh scattering that is performed in a same chamber filled with an argon gas having known density. The absolute value of the electron density nₑ may be given by the following specific calculation expression.

$${n}_{e} = \frac{{I}_{T}}{{I}_{R}} \frac{{σ}_{R}}{{σ}_{T} {S}_{i}} {n}_{0} \qquad [ Math . 4 ]$$

In the expression, n₀ may be density of the argon gas, σ_{R} may be a cross section of the Rayleigh scattering of the argon gas, σ_{T} may be an entire cross section of the Thomson scattering, and Sᵢ is an integral value of a spectrum function of the ionic term at a wavelength difference. The integral value Sᵢ of the spectrum function of the ionic term at the wavelength difference may be given by the following expression.

$${S}_{i} = \frac{Z {α}^{4}}{( 1 + {α}^{2} ) \{ 1 + {α}^{2} ( 1 + {ZT}_{e} \text{/} {T}_{j} ) \}} \qquad [ Math . 5 ]$$

Note that a ratio of the cross section of the Rayleigh scattering of the argon gas and the entire cross section of the Thomson scattering may be σ_{R}/σ_{T}=1100 at this occasion.

### (3.4 Issues)

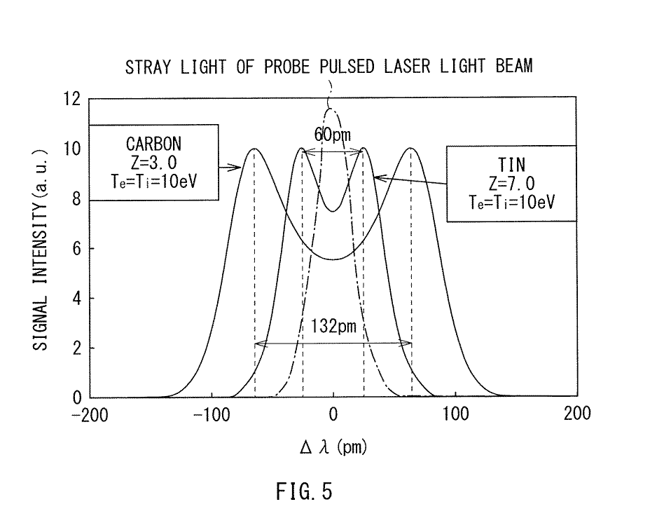

FIG. 5 schematically illustrates an example of a spectrum waveform of stray light of the probe pulsed laser light beam 31P and the ionic term in the Thomson scattered light 31T. In FIG. 5, a horizontal axis may indicate the wavelength difference Δλ from the wavelength λ₀ of the probe pulsed laser light beam 31P defined as a center wavelength, and a vertical axis indicate signal intensity. FIG. 5 schematically illustrates an example of a spectrum waveform in a case in which the target 27 is carbon and a spectrum waveform in a case in which the target 27 is tin.

When the ionic term is measured by the ordinary spectrometer 130, stray light by the probe pulsed laser light beam 31P may be large, and a spectrum waveform of a composite of the ionic term and the stray light of the probe pulsed laser light beam 31P may be measured, as illustrated in FIG. 5. This may make it difficult to measure the ionic term with high accuracy. In particular, in the case in which the target 27 is tin, a difference Δλₚ between two peak wavelengths each measured as the ionic term may be as narrow as 60 pm, which may make it difficult to separate spectrum wavelengths of the ionic term and the stray light of the probe pulsed laser light beam 31P from each other.

### 4. First Embodiment

### Thomson Scattering Measurement System Including Wavelength Filter

(4.1 Configuration)

(4.1.1 Entire Configuration of System)

FIG. 6 schematically illustrates a configuration example of a Thomson scattering measurement system applied to an EUV light generating system according to a first embodiment. Note that substantially same components as the components in FIG. 2 are denoted by same reference numerals, and redundant description thereof is omitted.

The Thomson scattering measurement system illustrated in FIG. 6 may include a wavelength filter 150 disposed upstream of the spectrometer 130 in a configuration in FIG. 2. A wavelength filter 150 may suppress light with a predetermined wavelength from entering the spectrometer 130. The light with the predetermined wavelength may be part of light containing the Thomson scattered light 31T. The predetermined wavelength may be substantially same as the wavelength λ₀ of the probe pulsed laser light beam 31P. A combination of the wavelength filter 150 and the spectrometer 130 may configure the spectrum measurement unit 140 that measures the spectrum waveform of the ionic term in the Thomson scattered light 31T.

The collimator lens 91, high reflection mirrors 95, 96a, and 96b, and a light concentrating lens 97 may be disposed in an optical path of the Thomson scattered light 31T between the window 36 of the chamber 2 and the wavelength filter 150. The collimator lens 91, the high reflection mirrors 95, 96a, and 96b, and the light concentrating lens 97 may be disposed so that an image of the plasma by the Thomson scattered light 31T is rotated by 270° and formed on the entrance slit 151 of the wavelength filter 150.

A high reflection mirror 98 and an off-axis parabolic mirror 99 may be provided as the laser concentrating optical system 22a for the drive pulsed laser light beam 31D. Surfaces of the high reflection mirror 98 and the off-axis parabolic mirror 99 may be coated with a film that reflects, at high reflectivity, laser light with a wavelength that is same as both a wavelength of a pre-pulsed laser light beam and a wavelength of a main pulsed laser light beam 31M. The pre-pulsed laser light beam and the main pulsed laser light beam 31M are described later.

The drive laser unit 3D may include a first pre-pulsed laser unit 3p1, a second pulsed laser unit 3p2, and a main pulsed laser unit 3M that are described later and illustrated in FIG. 8. A first pre-pulse emission trigger TGp1, a second pre-pulse emission trigger TGp2, and a main pulse emission trigger TGm1 may be inputted as a drive pulse emission trigger TG1 from the delay circuit 53 to the drive laser unit 3D.

The wavelength filter 150 may include an entrance slit 151, a high reflection mirror 141, a collimator optical system 142, a grating 143, a grating 144, a light concentrating optical system 145, and an intermediate slit 152. The wavelength filter 150 may further include a collimator optical system 161, a grating 162, a grating 163, a light concentrating optical system 164, and a high reflection mirror 165.

The gratings 143 and 144 each may be a dispersion optical system that disperses the light containing the Thomson scattered light 31T spatially depending on a wavelength of that light. The gratings 143 and 144 may be dispersion gratings that diffract the light containing the Thomson scattered light 31T depending on the wavelength of that light.

The entrance slit 151 may be so disposed as to allow the image of the plasma by the Thomson scattered light 31T formed by the light concentrating lens 97 to enter the entrance slit 151. The high reflection mirror 141 may be so disposed as to reflect the Thomson scattered light 31T having passed through the entrance slit 151 at high reflectivity to thereby enter the collimator optical system 142. The collimator optical system 142 may be so disposed as to convert the light having passed through the entrance slit 151 into first collimated light. The grating 143 may be disposed so that the first collimated light enters the orating 143 at a predetermined entrance angle α1 and is diffracted at substantially a diffraction angle β1 by the grating 143. The grating 144 may be disposed so that diffracted light by the grating 143 enters the grading 144 at the predetermined angle α1 and is diffracted at substantially the diffraction angle β1 by the grating 144. The light concentrating optical system 145 may be so disposed as to allow the diffracted light by the grating 144 to be concentrated thereunto.

The intermediate slit 152 may include a blocking member 152a that blocks light with a predetermined wavelength in dispersed light derived from the gratings 143 and 144. The blocking member 152a may be disposed linearly in a substantially central part of the intermediate slit 152, as illustrated in FIG. 7. The intermediate slit 152 may be disposed on a focal surface of the light concentrating optical system 145. The intermediate slit 152 may block the light with the predetermined wavelength in the dispersed light derived from the gratings 143 and 144 with use of the blocking member 152a, and may allow light having entered both sides of the blocking member 152a to pass therethrough.

The gratings 162 and 163 each may be an inverse dispersion optical system that performs inverse dispersion of the dispersed light, having been subjected to the blocking of the light with the predetermined wavelength by the blocking member 152a, spatially depending on a wavelength of that dispersed light. The gratings 162 and 163 may be inverse dispersion gratings that diffract the dispersed light, having been subjected to the blocking of the light with the predetermined wavelength by the blocking member 152a, depending on the wavelength of that dispersed light.

The collimator optical system 161 may be so disposed as to convert the light having passed through the both sides of the blocking member 152a into second collimated light. The grating 162 may be disposed so that the second collimated light enters the grating 162 at an entrance angle β1 and is diffracted at substantially a diffraction angle α1 by the grating 162. The grating 163 may be disposed so that the diffracted light by the grating 162 enters the grating 163 at the predetermined entrance angle β1 and is diffracted at substantially the diffraction angle α1 by the grating 163. The light concentrating optical system 164 may be so disposed as to allow the diffracted light diffracted by the grating 163 to be concentrated thereonto. The high reflection mirror 165 may be so disposed as to form, on the entrance slit 131 of the spectrometer 130, an image of the diffracted light having passed through the light concentrating optical system 164.

Specifications of optical devices configuring the wavelength filter 150 and the spectrometer 130 may be as follows. The collimator optical systems 132, 142, and 161, and the light concentrating optical systems 134, 145, and 164 each may have a lens having an effective diameter of 60 mm and a focal length of 486 mm, and the lens may be subjected to chromatic aberration correction in a measurement wavelength region. The gratings 133, 143, 144, 162, and 163 may he blazed gratings having 2400 grooves/mm. Slit widths of the entrance slits 131 and 151 may be about 20 μm. The blocking member 152a may be a tungsten wire having a diameter of 100 μm.

The EUV light generation controller 5 may calculate a plasma parameter indicating a characteristic of the plasma from the spectrum waveform of the ionic term in the Thomson scattered light 31T measured by the spectrum measurement unit 140. Moreover, the EUV light generation controller 5 may control the drive laser unit 3D so as to allow a characteristic of the drive pulsed laser light beam 31D to be optimized on the basis of a detection value derived from the energy sensor 28 and on the plasma parameter. The EUV light generation controller 5 may also control the target feeding unit 70 so as to allow a target diameter of the target 27 to be optimized on the basis of the detection value derived from the energy sensor 28 and on the plasma parameter.

### (4.1.2 Configuration of Drive Laser Unit)

FIG. 8 schematically illustrates a configuration example of the drive laser unit 3D.

The drive pulsed laser light beam 31D may include a pre-pulsed laser light beam and a main pulsed laser light beam 31M. The pre-pulsed laser light beam may diffuse the target 27. The main pulsed laser light beam 31M may turn the diffused target 27 into the plasma. The drive laser unit 3D may include a pre-pulsed laser unit 3P and the main pulsed laser unit 3M. The pre-pulsed laser unit 3P may output the pre-pulsed laser light beam, and the main pulsed laser unit 3M may output the main pulsed laser light beam 31M.

The drive laser unit 3D may further include a beam adjuster 171, a beam adjuster 172, and a beam adjuster 173. The drive laser unit 3D may further include a high reflection mirror 174, a polarizer 175, a dichroic mirror 176, and a λ/2 plate 177. Each of the beam adjuster 171, the beam adjuster 172, and the beam adjuster 173 may include a concave lens 178a and a convex lens 178b. Each of the beam adjusters 171, 172, and 173 may adjust a clearance between the concave lens 178a and the convex lens 178b to adjust a beam diameter in the plasma generation region 25. The present embodiment involves an example in which the concave lens 178a and the convex lens 178b are combined as the beam adjuster; however, the beam adjuster is not limited thereto. A combination of a concave mirror and a convex mirror, a combination of a lens and a mirror, or a deformable mirror having a deformed mirror surface may be adopted as the beam adjuster.

The pre-pulsed laser unit 3P may include the first pre-pulsed laser unit 3p1 and the second pre-pulsed laser unit 3p2. The first pre-pulsed laser unit 3p1 may output a first pre-pulsed laser light beam 31p1, and the second pre-pulsed laser unit 3p2 may output a second pre-pulsed laser light beam 31p2. The first pre-pulsed laser unit 3p1 may be, for example, a picosecond laser unit that outputs pulsed laser light having a pulse width of less than 1 ns. The picosecond laser unit may include a master oscillator of a Nd:YVO mode locked laser and a Nd:YAG crystal regenerative amplifier. The first pre-pulsed laser unit 3p1 may output, for example, pulsed laser light having a wavelength of 1.06 μm and a pulse width of about 14 ps at full width at half maximum. The second pre-pulsed laser unit 3p2 may be a YAG laser unit, and may output pulsed laser light having a wavelength of 1.06 μm and a pulse width of about 6 ns at full width at half maximum.

The main pulsed laser unit 3M may be a CO₂ laser unit, and may output pulsed laser light having a wavelength of 10.6 μm and a pulse width of about 15 ns at full width at half maximum.

The polarizer 175 may be so disposed as to allow an optical path axis of the first pre-pulsed laser light beam 31p1 to be substantially coincident with an optical path axis of the second pre-pulsed laser light beam 31p2 in the polarizer 175. The dichroic mirror 176 may be so disposed as to allow the optical path axes of the first pre-pulsed laser light beam 31p1 and the second pre-pulsed laser light beam 31p2 to be substantially coincident with an optical path axis of the main pulsed laser light beam 31M in the dichroic mirror 176.

The dichroic mirror 176 may be configured of a diamond substrate including a surface coated with a film that reflects, for example, light with a wavelength of 1.06 μm at high reflectivity and allows light with a wavelength of 10.6 μm to pass therethrough at high transmittance.

The λ/2 plate 177 may be so disposed as to rotate a polarization surface of the second pre-pulsed laser light beam 31p2 by 90°. The λ/2 plate 177 may allow the second pre-pulsed laser light beam 31p2 to enter the polarizer 175 in a form of S-polarized light. The polarizer 175 may multiplex the first pre-pulsed laser light beam 31p1 having entered the polarizer 175 in a form of P-polarized light and the second pre-pulsed laser light beam 31p2 having entered the polarizer 175 in the form of S-polarized light. Note that in FIG. 8, the S-polarized light may be polarized light in a direction perpendicular to a paper surface, and the P-polarized light may be polarized light in a direction parallel to the paper surface. In FIG. 8, a black circle mark S provided in an optical path may indicate a polarization direction perpendicular to the paper surface, and a solid line P provided in the optical path orthogonal to the optical path may indicate a polarization direction parallel to the paper surface.

The main pulsed laser unit 3M may be coupled to the delay circuit 53 so as to receive the main pulse emission trigger TGm1. The first pre-pulsed laser unit 3p1 may be coupled to the delay circuit 53 so as to receive the first pre-pulse emission trigger TGp1. The second pre-pulsed laser unit 3p2 may be coupled to the delay circuit 53 so as to receive the second pre-pulse emission trigger TGp2.

The EUV light generation controller 5 may control one or more of the first pre-pulsed laser unit 3p1, the second pre-pulsed laser unit 3p2, and the main pulsed laser unit 3M on the basis of the detection value derived from the energy sensor 52 and on the plasma parameter. Such control may be performed so as to control a beam parameter as a characteristic of one or more of the first pre-pulsed laser light beam 31p1, the second pre-pulsed laser light beam 31p2, and the main pulsed laser light beam 31M to optimize generation of EUV

### (4.2 Operation)

(4.2.1 Operation of Entire System)

In the Thomson scattering measurement system illustrated in FIG. 6, the image of the plasma by the Thomson scattered light 31T may be rotated by 270° and formed on the entrance slit 151 of the wavelength filter 150 via the collimator lens 91, the high reflection mirrors 95, 96a, and 96b, and the light concentrating lens 97. A longitudinal direction of an aperture of the entrance slit 151 of the wavelength filter 150 may be substantially coincident with an axis direction of the drive pulsed laser light beam 31D. Light having passed through the entrance slit 151 may be collimated by the collimator optical system 142, and may be diffracted by the gratings 143 and 144. The gratings 143 and 144 may diffract the light containing the Thomson scattered light 31T so as to disperse the light containing the Thomson scattered light 31T spatially depending on the wavelength of that light. The image of the entrance slit 151 may be formed on the blocking member 152a of the intermediate slit 152 by the light concentrating optical system 145 via the collimator optical system 142 and the gratings 143 and 144.

The blocking member 152a may block the light with the predetermined wavelength, which is substantially same as the wavelength λ₀ of the probe pulsed laser light beam 31P, in the light having entered the intermediate slit 152. The Thomson scattered light 31T within or higher than a predetermined wavelength range from the wavelength λ₀ of the probe pulsed laser light beam 31P may pass through the intermediate slit 152 The light having passed through the intermediate slit 152 may be collimated by the collimator optical system 161, and thereafter may be diffracted by the gratings 162 and 163 by dispersion inverse to dispersion by the gratings 143 and 144. An image of the diffracted light may he formed as the image of the entrance slit 151 on the entrance slit 131 of the spectrometer 130 by the light concentrating optical system 164 via the high reflection mirror 165. The diffracted light may pass through the entrance slit 131 of the spectrometer 130, and the image of the diffracted light may be formed on the light reception surface of the ICCD camera 135 as a diffraction image of the entrance slit 131 via the collimator optical system 132, the grating 133, and the light concentrating optical system 134.

### (Reduction of Stray Light by Wavelength Filter 150)

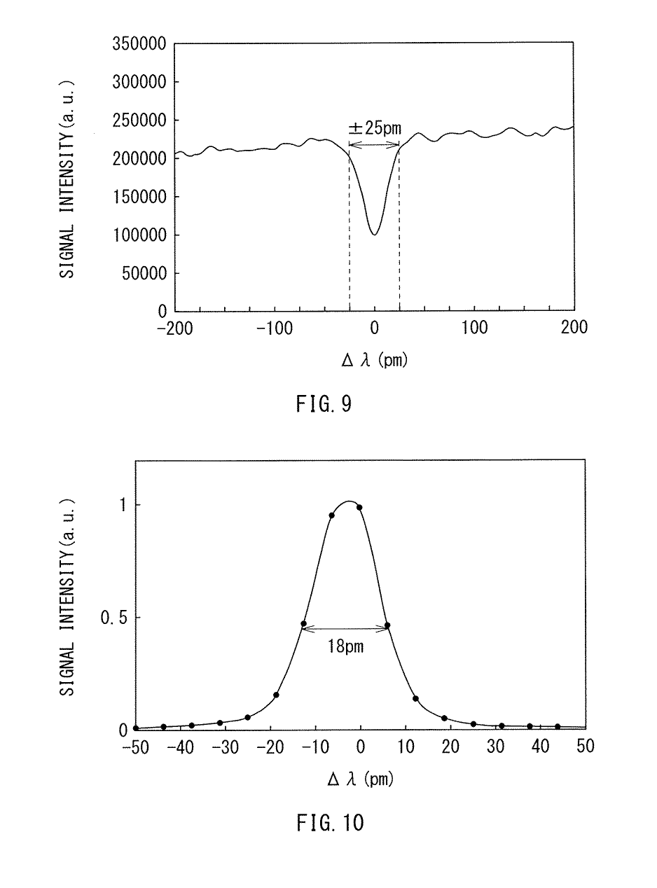

FIG. 9 illustrates an intensity distribution of a spectrum measured by the ICCD camera 135 when light generated from the plasma enters the entrance slit 151 of the wavelength filter 150 in the Thomson scattering measurement system in FIG. 6. In FIG. 9, a horizontal axis may indicate the wavelength difference Δλ from the wavelength of the probe pulsed laser light beam 31P defined as a center wavelength, and a vertical axis may indicate signal intensity.

As illustrated in FIG. 9, the wavelength filter 150 may suppress transmission of a spectrum within a range of ±25 pm from the wavelength λ₀=532.0 nm of the probe pulsed laser light beam 31P. As illustrated in FIG. 5 mentioned above, the difference Δλp between the two peak wavelengths each measured as the ionic term in the Thomson scattered light 31T may be, for example, about 60 pm. In order to measure the difference Δλp=60 pm between the two peak wavelengths of the ionic term, the wavelength width Δλs of light suppressed by the wavelength filter 150 may be preferably at least Δλs=50 pm.

In other words, the wavelength width 66 λs of the light suppressed by the wavelength filter 150 and the difference Δλp between the two peak wavelengths each measured as the ionic term may preferably satisfy the following relationship.

Δλs/Δλp≦50/60=0.833

### (Device Function of Spectrometer 130)

FIG. 10 schematically illustrates an example of a spectrum waveform measured in a case in which the blocking member 152a is removed to cause Rayleigh scattered light of the probe pulsed laser light beam 31P to enter the spectrum measurement unit 140 in the Thomson scattering measurement system in FIG. 6. In FIG. 10, a horizontal axis may indicate the wavelength difference Δλ from the wavelength λ₀ of the probe pulsed laser light beam 31P defined as a center wavelength, and a vertical axis may indicate signal intensity.

A spectral line width of single longitudinal mode laser light that is the probe pulsed laser light beam 31P may be extremely narrow. Accordingly, the spectrum waveform measured by the spectrum measurement unit 140 may serve as a device function of the spectrometer 130 of the spectrum measurement unit 140. A full width at half maximum Δλf of the device function of the spectrometer 130 may be 18 pm, as illustrated in FIG. 10. As will be described later, the ionic term in the Thomson scattered light 31T may be measured by the spectrum measurement unit 140 with the device function.

The full width at half maximum Δλf of the device function of the spectrometer 130 and the difference Δλp between the two peak wavelengths each measured as the ionic term in the Thomson scattered light 31T may preferably satisfy the following relationship.

Δλf/Δλp≦18/60=0.3

### (4.2.2 Control Timings by EUV Light Generation Controller)

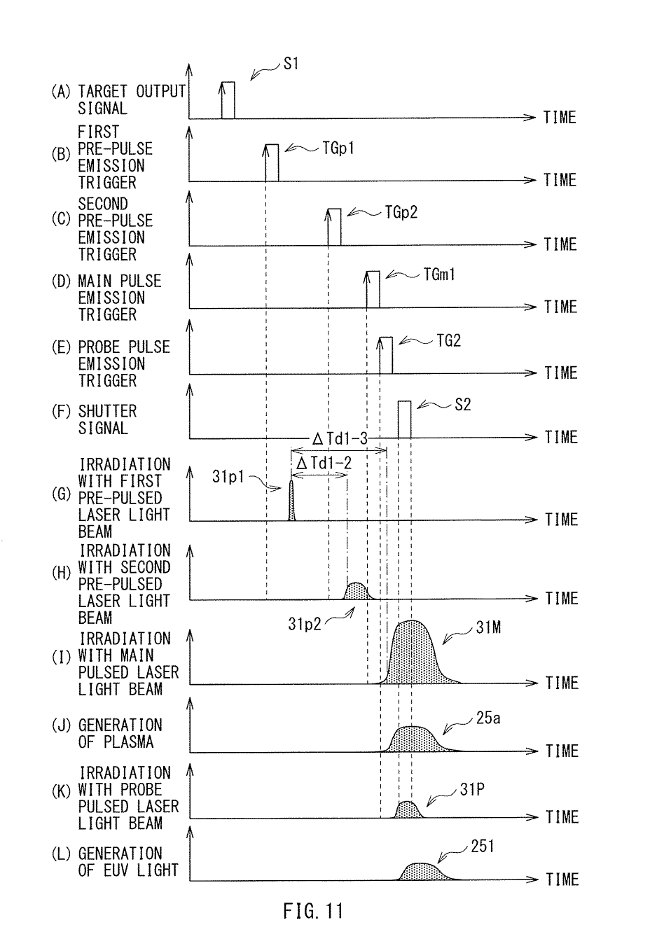

FIG. 11 is a timing chart illustrating an example of control timings by the EUV light generation controller 5. Note that in (A) to (F) of FIG. 11, a vertical axis may indicate a signal level. In (G) to (I), (K), and (L) of FIG. 11, a vertical axis may indicate intensity of light. In (J) of FIG. 11, a vertical axis may indicate density or temperature of the plasma.

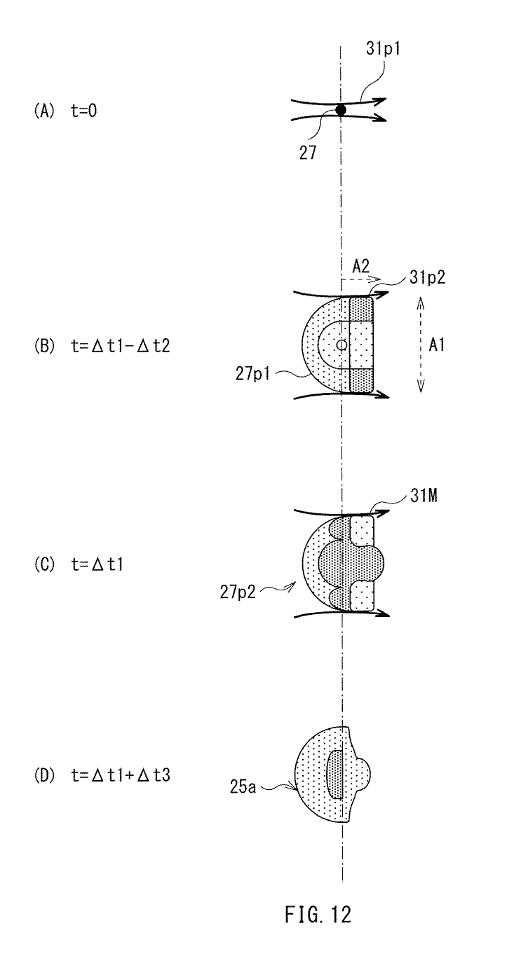

FIG. 12 schematically illustrates states until the target 27 is turned into the plasma to generate the EUV light 251. Note that (A), (B), (C), and (D) of FIG. 12 may schematically illustrate a state at a time t=0, a state at the time t=Δt1−Δt2, a state at the time t=Δt1, and a state at the time t=Δt1+Δt3, respectively.

First, with reference to FIG. 12, description is given of a state in which a plasma 25a is generated from the target 27. As illustrated in (A) of FIG. 12, at the time t=0, the target 27 may be irradiated with the picosecond first pre-pulsed laser light beam 31p1 having a spot diameter slightly larger than the diameter of the target 27.

The target 27 may be broken by irradiation with the first pre-pulsed laser light beam 31p1 to produce a second-order target 27p1 that is diffused in a semi-dome-like fashion. The second-order target 27p1 may he diffused in a semi-dome-like fashion to a direction A1 orthogonal to a laser traveling direction A2 and a direction opposite to the laser traveling direction A2. The second-order target 27p1 may be diffused also in the same direction as the laser traveling direction A2. The second-order target 27p1 may be irradiated with the second pre-pulsed laser light beam 31p2 having a spot diameter substantially same as a size of the second-order target 27p1 at the time t=66 t1−Δt2, as illustrated in (B) of FIG. 12.

A pre-plasma may be generated by irradiation of the second-order target 27p1 with the second pre-pulsed laser light beam 31p2 to produce a third-order target 27p2. The third-order target 27p2 may be irradiated with the main pulsed laser light beam 31M having a spot diameter substantially same as a size of the third-order target 27p2 at the time t=Δt1, as illustrated in (C) of FIG. 12

Irradiation of the third-order target 27p2 with the main pulsed laser light beam 31M may cause generation of a plasma at the time t=Δ1+Δt3 to thereby generate the EUV light 251, as illustrated in (D) of FIG. 12.

Next, with reference to FIG. 11, description is given of control timings by the EUV light generation controller 5.

The EUV light generation controller 5 may output the delay data Dt0 to the delay circuit 53. The delay data Dt0 may indicate delay times of various signals. The various signals may include the target output signal S1, the probe pulse emission trigger TG2, the first pre-pulse emission trigger TGp1, the second pre-pulse emission trigger TGp2, the main pulse emission trigger TGm1, and the shutter signal S2.

As illustrated in (A) of FIG. 11, the EUV light generation controller 5 may output the target output signal S1. The EUV light generation controller 5 may also output the trigger signal TG0 to the delay circuit 53 so as to allow each of the various signals mentioned above to be generated at a predetermined delay time. The EUV light generation controller 5 may output the trigger signal TG0 substantially simultaneously with the target output signal S1. When the target output signal S1 is inputted to the target feeding unit 70, the target 27 in the droplet form may be outputted from the nozzle 62 of the target feeding unit 70.

Next, as illustrated in (B) of FIG. 11, the first pre-pulse emission trigger TGp1 may be outputted from the delay circuit 53 to the first pre-pulsed laser unit 3p1. When the first pre-pulse emission trigger TGp1 is inputted to the first pre-pulsed laser unit 3p1, the first pre-pulsed laser unit 3p1 may output the first pre-pulsed laser light beam 31p1. The target 27 having reached the plasma generation region 25 may be irradiated with the first pre-pulsed laser light beam 31p1 by the laser concentrating optical system 22a, as illustrated in (G) of FIG. 11 and (A) of FIG. 12. As a result, the target 27 may be broken to produce the second-order target 27p1 diffused in a semi-dome-like fashion, as illustrated in (B) of FIG. 12.

Next, as illustrated in (C) of FIG. 11, the second pre-pulse emission trigger TGp2 may he outputted from the delay circuit 53 to the second pre-pulsed laser unit 3p2. When the second pre-pulse emission trigger TGp2 is inputted to the second pre-pulsed laser unit 3p2, the second pre-pulsed laser unit 3p2 may output the second pre-pulsed laser light beam 31p2. The second-order target 27p1 may be irradiated with the second pre-pulsed laser light beam 31p2 by the laser concentrating optical system 22a, as illustrated in (H) of FIG. 11 and (B) of FIG. 12. As a result, the second-order target 27p1 may be turned into a pre-plasma to produce the third-order target 27p2, as illustrated in (C) of FIG. 12.

Next, as illustrated in (D) of FIG. 11, the main pulse emission trigger TGm1 may be outputted from the delay circuit 53 to the main pulsed laser unit 3M. When the main pulse emission trigger TGm1 is inputted to the main pulsed laser unit 3M, the main pulsed laser unit 3M may output the main pulsed laser light beam 31M. The third-order target 27p2 may be irradiated with the main pulsed laser light beam 31M by the laser concentrating optical system 22a, as illustrated in (I) of FIG. 11 and (C) of FIG. 12. As a result, the third-order target 27p2 may be turned into a plasma to generate the EUV light 251, as illustrated in (J) and (L) of FIG. 11 and (D) of FIG. 12.

The energy sensor 52 may detect energy of the EUV light 251 to output a detection value of the detected energy to the EUV light generation controller 5.

Next, the probe pulse emission trigger TG2 may be outputted from the delay circuit 53 to the probe laser unit 30, as illustrated in (E) of FIG. 11. When the probe pulse emission trigger TG2 is inputted to the probe laser unit 30, the probe pulsed laser light beam 31P may be outputted, and the plasma 25a may be irradiated with the probe pulsed laser light beam 31P, as illustrated in (K) of FIG. 11.

The Thomson scattered light 31T of the probe pulsed laser light beam 31P from the plasma ay enter the entrance slit 151 of the wavelength filter 150 of the spectrum measurement unit 14. Light having been subjected to suppression of passage of light with a predetermined wavelength by the wavelength filter 150 may enter the entrance slit 131 of the spectrometer 130. The predetermined wavelength may be substantially same as the wavelength λ₀ of the probe pulsed laser light beam 31P. The diffraction image of the entrance slit 131 may be formed on the light reception surface of the ICCD camera 135.

Next, the shutter signal S2 may be outputted from the delay circuit 53 to the ICCD camera 135, as illustrated in (F) of FIG. 11. When the shutter signal S2 is inputted to the ICCD camera 135, the ICCD camera 135 may be turned to the shutter open state only for a time equal to the pulse width of the shutter signal S2, and may measure an image during the time. Since the diffracted light varies in diffraction angle depending on the wavelength of that light, the spectrum waveform of the ionic term in the Thomson scattered light 31T during the time when the shutter signal S2 is inputted may be measured on the light reception surface of the ICCD camera 135. The ICCD camera 135 may output a result of such measurement as image data to the EUV light generation controller 5.

At this occasion, the delay time of the first pre-pulse emission trigger TGp1 and the delay time of the second pre-pulse emission trigger TGp2 may be adjusted so as to make a time Δtd1-2 variable. The time Δtd1-2 may he a time from irradiation of the target 27 with the first pre-pulsed laser light beam 31p1 to irradiation of the target 27 with the second pre-pulsed laser light beam 31p2. The delay time of the first pre-pulse emission trigger TGp1 and the delay time of the main pulse emission trigger TGm1 may be adjusted so as to make a time Δtd1-3 variable. The time Δtd1-3 may be a time from irradiation of the target 27 with the first pre-pulsed laser light beam 31p1 to irradiation of the target 27 with the main pulsed laser light beam 31M.

Moreover, timings of the probe pulse emission trigger TG2 and the shutter signal S2 may be adjusted to a time when the plasma 25a is desired to be measured.

### (Result of Measurement of Spectrum Waveform of Thomson Scattered Light 31T)

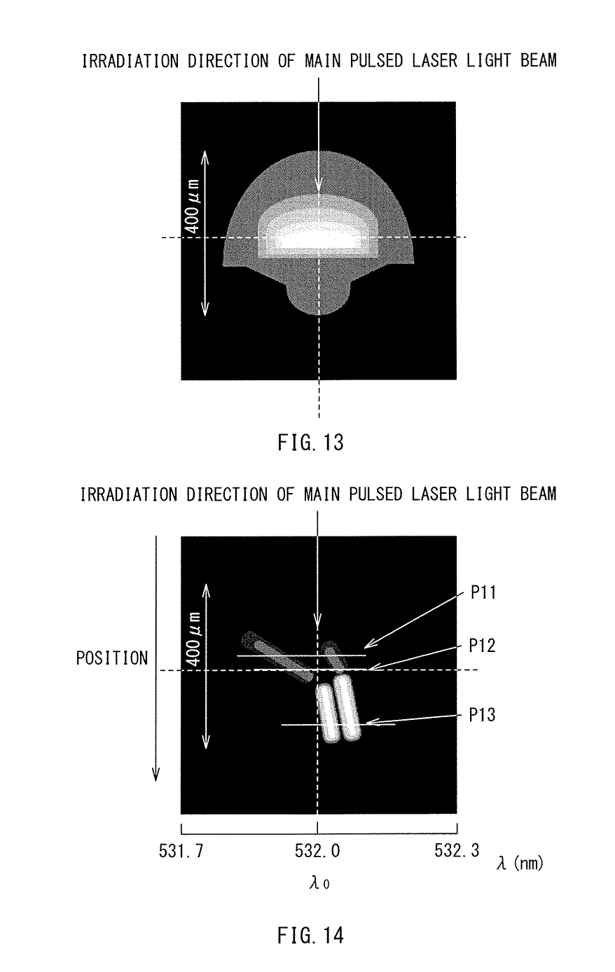

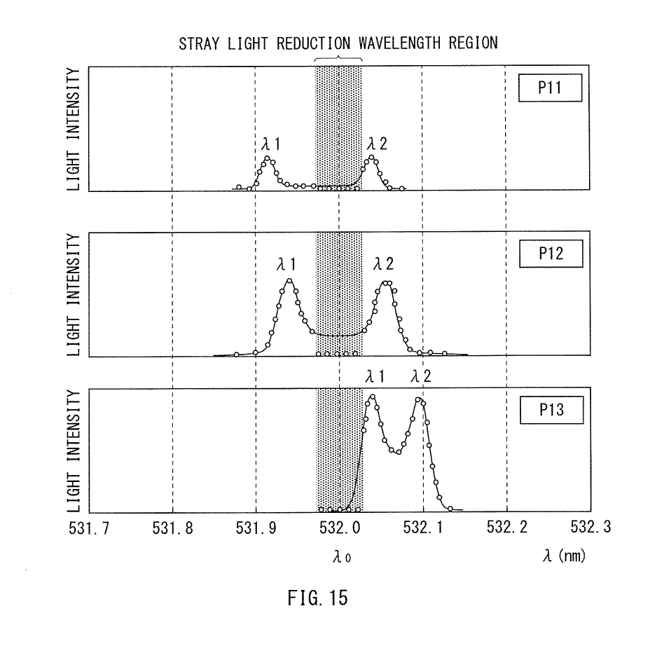

With reference to FIGS. 13 to 15, description is given of an example of a result of measurement of the spectrum waveform of the ionic term in the Thomson scattered light 31T. FIG. 13 schematically illustrates an image in an emission state of the EUV light 251. FIG. 14 schematically illustrates a spectrum image of the ionic term in the Thomson scattered light 31T. In FIG. 14, a vertical direction indicates a position, and a horizontal direction indicates a wavelength. FIG. 15 schematically illustrates a spectrum waveform of the ionic term in the Thomson scattered light 31T at each of positions P11, P12, and P13 in FIG. 14. A region around the wavelength λ₀ of the probe pulsed laser light beam 31P may be a stray light reduction wavelength region by the wavelength filter 150, as illustrated in FIG. 15.

These diagrams show results of measurement when the target 27 is irradiated with one or more pre-pulsed laser light beams and after a predetermined time, the diffused target 27 is irradiated with the main pulsed laser light beam 31M to turn the target 27 into a plasma to thereby generate the EUV light 251. The plasma 25a is irradiated with the probe pulsed laser light beam 31P at a predetermined time after the target 27 is irradiated with the main pulsed laser light beam 31M to be turned into the plasma.

Two peak wavelengths of the spectrum waveform of the ionic term in FIG. 15 may be indicated by λ1 and λ2 in order from short wavelength side, and an average value λav (=(λ1+λ2)/2) of the peak wavelengths λ1 and λ2 may be determined.

In FIG. 15, a solid curve may be a curve calculated by calculating the spectrum of the ionic term from the plasma parameter and performing convolution integral of the device function of the spectrometer 130 in FIG. 10. The plasma parameter may include the ionic valence Z, the electron density nₑ, the electron temperature Tₑ, and the ion temperature Tᵢ. As can be seen from FIG. 15, the solid curve that indicates a calculation value is substantially coincident with a measured value.

Execution of calculation as mentioned above may allow for calculation of the plasma parameter at a time of the measurement and a measurement position of the plasma 25a. In FIG. 15, the average value λav of the two peak wavelengths of the ionic term is shifted from the wavelength λ₀ of the probe pulsed laser light beam 31P by a Doppler effect of light caused by motion of ions. Accordingly, a motion direction and velocity v of ions may be estimated from the average value λav of the two peak wavelengths of the ionic terra. The velocity v of ions may be determined by the following expression (1) that indicates the Doppler effect of light. In the expression (1), c indicates light velocity.

λav=λ₀(1−v/c)/(1−v²/c²)^{0.5} . . . (1)

At this occasion, ions hardly move at the position P12 where the average value λav of the two peak wavelengths of the ionic term is substantially coincident with the wavelength λ₀ of the probe pulsed laser light beam 31P, and the position P12 is considered as a central position of the plasma 25a. It may be considered that at the position P11 on upstream side of the central position, the ions move to entrance side of the main pulsed laser light beam 31M, and at the position P13 on downstream side of the central position, the ions move to a traveling direction of the main pulsed laser light beam 31M.

### (4.3 Workings)

According to the first embodiment, in the wavelength filter 150, the diffraction image of the entrance slit 151 is formed, and the blocking member 152a blocks the light with the predetermined wavelength, which makes it possible to suppress stray light around the wavelength λ₀ of the probe pulsed laser light be 31P. Light having been subjected to suppression of stray light is dispersed by the spectrometer 130, which makes it possible to measure the spectrum waveform of the ionic term in the Thomson scattered light 31T with high accuracy.

### (4.4 Modification Examples)

The embodiment illustrated in FIG. 6 involves an example in which light is diffracted twice by two gratings 143 and 144 to form the diffraction image of the entrance slit 151 in the wavelength filter 150; however, the embodiment is not limited thereto. For example, substantially similar performance may be achieved by using one grating having a size twice as large as each of the gratings 143 and 144 and doubling a lens focal length between the collimator optical system 142 and the light concentrating optical system 145 and an effective diameter.

Moreover, in the embodiment of the control timings illustrated in FIG. 11, the pulse width of the probe pulsed laser light beam 31P and the pulse width of the shutter signal S2 may be adjusted to be substantially equal to each other and to be synthesized with each other. The shutter signal S2 of the ICCD camera 135 may be outputted during plasma emission to measure the Thomson scattered light 31T. The control timings are not limited to the embodiment. For example, the pulse width of the probe pulsed laser light beam 31P may be increased, and the pulsed width of the shutter signal S2 of the ICCD camera 135 may become shorter than the pulse width of the probe pulsed laser light beam 31P. Thus, the timing of the shutter signal S2 may be changed. Moreover, the pulse width of the shutter signal S2 of the ICCD camera 135 may become longer than the pulse width of the probe pulsed laser light beam 31P to change a timing of irradiation with the probe pulsed laser light beam 31P, and measurement may be performed.

(Case in which Target Material is Gd and Tb and Enhancement of Resolution of Spectrometer)

FIG. 16 schematically illustrates, as a modification example of the spectrometer 130, an example of a spectrometer 130A having enhanced resolution that allows the full width at half maximum of the device function to be about 10 pm. The spectrometer 130A may have a configuration in which a grating 136 is further included in the configuration of the spectrometer 130 illustrated in FIG. 6. The grating 136 may have specifications substantially same as specifications of the grating 133. The grating 136 may be disposed in an optical path between the grating 133 and the light concentrating optical system 134.

In the spectrometer 130A, the diffraction image of the entrance slit 131 may be formed on the light reception surface of the ICCD camera 135 via the collimator optical system 132, the grating 133, the grating 136, and the light concentrating optical system 134.

FIG. 17 schematically illustrates an example of a spectrum waveform of an ionic term to be measured by the spectrometer 130A illustrated in FIG. 16. In FIG. 17, a horizontal axis may indicate the wavelength difference Δλ from the wavelength λ₀ of the probe pulsed laser light beam 31P defined as a center wavelength, and a vertical axis may indicate signal intensity. FIG. 17 illustrates the spectrum waveform obtained by performing convolution integral of the device function having the full width at half maximum of about 10 pm on the spectrum waveform of the ionic term theoretically determined from the plasma parameter. FIG. 17 illustrates the spectrum waveforms in cases in which the material of the target 27 is tin (Sn), terbium (Tb), and gadolinium (Gd). The spectrum waveform in the case in which the material of the target 27 is terbium is substantially coincident with the spectrum waveform in the case in which the material of the target 27 is gadolinium. In FIG. 17, in the case in which the material of the target 27 is terbium and gadolinium, calculation is executed under a condition that the electron temperature Tₑ is 100 eV and the ionic valence Z is 18. In the case in which the material of the target 27 is tin, calculation is executed under a condition that the electron temperature Tₑ is 40 eV and the ionic valence Z is 10.

Attention is given to terbium and gadolinium as materials that generate the EUV light 251 with a wavelength of 6.X nm. Herein, 6.X nm may be a wavelength around 6.7 nm. In this case, the difference Δλp between the two peak wavelengths each measured as the ionic term is wider than that in the case in which the material of the target 27 is tin, which makes it possible to measure the ionic term in the Thomson scattered light 31T by the spectrum measurement unit 140 according to the embodiment of the present disclosure.

### 5. Second Embodiment

### EUV Light Generating System Including Thomson Scattering Measurement System

(5.1 Configuration)

(5.1.1 Entire Configuration of System)

FIG. 18 schematically illustrates a configuration example of an EUV light generating system including a Thomson scattering measurement system according to a second embodiment of the present disclosure. Note that substantially same components as the components in FIG. 6 are denoted by same reference numerals, and redundant description thereof is omitted.

As illustrated in FIG. 18, a dichroic mirror 344 may be provided. The dichroic mirror 344 may perform multiplexing so as to allow the optical path of the drive pulsed laser light beam 31D to be substantially coincident with the optical path of the probe pulsed laser light beam 31P. Accordingly, the drive pulsed laser light beam 31D and the probe pulsed laser light beam 31P may substantially coaxially enter the inside of the chamber 2 from one window 21. The dichroic mirror 344 may be configured of a diamond substrate including a surface coated with a film that reflects the probe pulsed laser light beam 31P at high reflectivity and allows the drive pulsed laser light beam 31D to pass therethrough at high transmittance. The window 21 may be configured of a diamond substrate including a surface coated with a film that suppresses reflection of the drive pulsed laser light beam 31D and the probe pulsed laser light beam 31P.

High reflection mirrors 341 and 342 may be disposed in an optical path between the drive laser unit 3D and the dichroic mirror 344. A high reflection mirror 343 and a beam adjuster 179 may be disposed in an optical path between the probe laser unit 30 and the dichroic mirror 344. The beam adjuster 179 may include a concave lens and a convex lens, and may adjust a clearance between these lenses to adjust a beam diameter in the plasma generation region 25 of the probe pulsed laser light beam 31P.

The chamber 2 may include the laser concentrating optical system 22a, a plate 82, and an XYZ-axis stage 84. The chamber 2 may further include the EUV light concentrating mirror 23, a mirror holder 81, the window 21, and the target collector 28. The window 21 may be fixed to an inside wall of the chamber 2 by sealing. The target feeder 26 and a target detector 40 may be attached to the chamber 2.

A fiber input optical system 153 used for measurement of the Thomson scattered light 31T from the plasma 25a may be further attached to the chamber 2 so as to face the plasma generation region 25. The Thomson scattered light 31T may be inputted to the spectrum measurement unit 140 from the fiber input optical system 153 via an optical fiber 154 and a fiber output optical system 155. The fiber input optical system 153 may include a window and a transfer optical system, and may form an image of the plasma 25a by the Thomson scattered light 31T on an end surface of an entrance sleeve of the optical fiber 154. The optical fiber 154 may be a bundled fiber in which a plurality of optical fibers are bundled. The fiber output optical system 155 may be so disposed as to allow the entrance slit 151 of the spectrum measurement unit 140 to be illuminated with light outputted from the optical fiber 154. The fiber output optical system 155 may include a light concentrating lens. The light concentrating lens may be so disposed as to allow the entrance slit 151 to be illuminated with the Thomson scattered light 31T outputted from an end surface of an output sleeve of the optical fiber 154.

The laser concentrating optical system 22a may include a plate 83, a holder 223, a holder 224, an off-axis parabolic mirror 221, and a plane mirror 222. The off-axis parabolic mirror 221 may be held to the plate 83 by the holder 223. The plane mirror 222 may be held to the plate 83 by the holder 224. The positions and the attitudes of the off-axis parabolic mirror 221 and the plane mirror 222 may be maintained so that the drive pulsed laser light beam 31D and the probe pulsed laser light beam 31P reflected by the off-axis parabolic mirror 221 and the plane 222 are concentrated onto the plasma generation region 25.

The plate 82 may be fixed to a wall inside the chamber 2. The EUV light concentrating mirror 23 may be a mirror including a spheroidal surface around the Z axis. The EUV light concentrating mirror 23 may be fixed to the plate 82 through the mirror holder 81 so that a first focal point of the spheroidal surface is substantially coincident with the plasma generation region 25. The through hole 24 through which the drive pulsed laser light beam 31D and the probe pulsed laser light beam 31P pass may be provided at a center part of the EUV light concentrating mirror 23.

A reflection surface of the plane mirror 222 and a reflection surface of the off-axis parabolic mirror 221 each may be coated with a film that reflects the drive pulsed laser light beam 31D and the probe pulsed laser light beam 31P at high reflectivity. A reflection surface of the EUV light concentrating mirror 23 may be coated with a multilayer film of Mo and Si.

In the chamber 2, the target detector 40 may be disposed on a trajectory of the target 27. The target detector 40 may measure a passage timing of the target 27. The target detector 40 may include the target sensor 4 and a light source section 45. The light source section 45 may include a light source 46 and an illumination optical system 47. The light source section 45 may be so disposed as to illuminate the target 27 at a predetermined position P1 on a trajectory Ya between the nozzle 62 of the target feeder 26 and the plasma generation region 25. The target sensor 4 may include an optical sensor 41 and a photodetection optical system 42 The target sensor 4 may be so disposed as to receive illumination light outputted from the light source section 45.

The target sensor 4 may be disposed on opposite side of the light source section 45 with the trajectory Ya of the target 27 in between. A window 21a and a window 21b may be attached to the chamber 2. The window 21a may be located between the light source section 45 and the trajectory Ya of the target 27. The light source section 45 may concentrate light onto the predetermined position P1 on the trajectory Ya of the target 27 through the window 21a. The window 21b may be located between the trajectory Ya of the target 27 and the target sensor 4. A detection position of the target 27 detected by the target sensor 4 may be substantially coincident with a light concentrated position by the light source section 45. The target sensor 4 may output a passage timing signal Tm1 as a detection signal of the target 27. The passage timing signal Tm1 may be a timing signal indicating a feed timing of the target 27. The passage timing signal Tm1 outputted from the target sensor 4 may be inputted to the EUV light generation controller 5. Thereafter, the passage timing signal Tm1 may be inputted to the delay circuit 53 as the trigger signal TG0 via the EUV light generation controller 5.

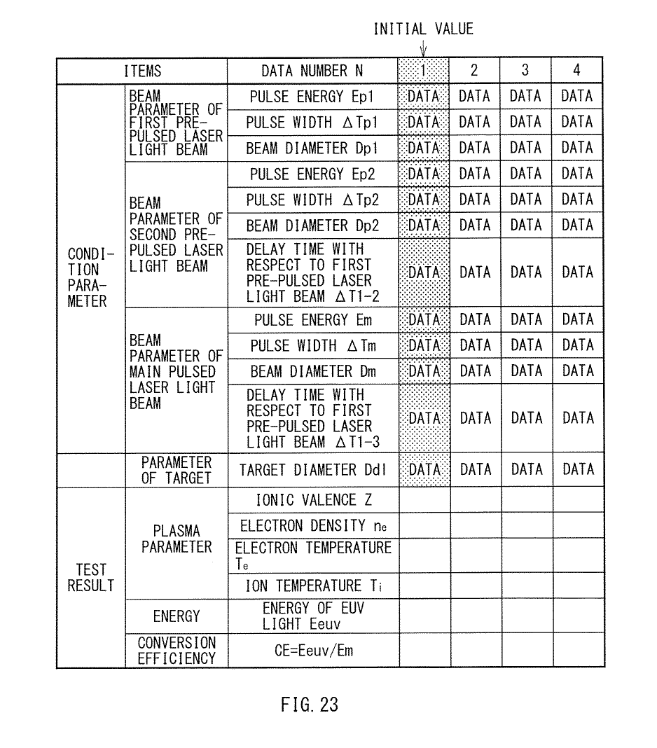

A generation signal may be inputted to the EUV light generation controller 5 from an exposure unit controller 6a of the exposure unit 6 as an external unit. The generation signal may trigger generation of the EUV light 251. The EUV light generation controller 5 may include a storage section 51. The storage section 51 may store, for example, data of a condition parameter for exposure and the plasma parameter. The condition parameter is described later and illustrated in FIG. 23. The EUV light generation controller 5 may be coupled to the drive laser unit 3D so as to transmit data Dt1 to the drive laser unit 3D. The data Dt1 may include, for example, desired pulse energy of the drive laser unit 3D, a pulse width, and a beam diameter in the plasma generation region 25. The EUV light generation controller 5 may be coupled to the target feeder 26 so as to transmit data Dt2 to the target feeder 26. The data Dt2 may include, for example, a target parameter such as a target diameter.

### (5.1.2 Configuration of Drive Laser Unit)

FIG. 19 schematically illustrates a configuration example of the drive laser unit 3D in the EUV light generating system illustrated in FIG. 18. Note that substantially same components as the components in FIG. 8 are denoted by same reference numerals, and redundant description thereof is omitted.

The drive laser unit 3D may have a configuration in which a one-axis stage is added to the concave lens 178a of each of the beam adjusters 171, 17 2, and 173. The one-axis stage may adjust a lens clearance in each of the beam adjusters 171 and 172 so as to allow for automatic adjustment of a beam diameter in the plasma generation region 25 of each of the first pre-pulsed laser light beam 31p1 and the second pre-pulsed laser light beam 31p2. The target 27 may be irradiated with the first pre-pulsed laser light beam 31p1 and the second pre-pulsed laser light beam 31p2. Moreover, the one-axis stage may adjust a lens clearance in the beam adjuster 173 so as to allow for automatic adjustment of a beam diameter in the plasma generation region 25 of the main pulsed laser light beam 31M.

The drive laser unit 3D may include a drive laser controller 54. The drive laser controller 54 may receive the data Dt1 outputted from the EUV light generation controller 5. Thereafter, the drive laser controller 54 may perform control based on data of the beam parameter of each of the first pre-pulsed laser light beam 31p1, the second pre-pulsed laser light beam 31p2, and the main pulsed laser light beam 31M. The beam parameter may be data such as pulse energy, the pulse width, and a beam diameter at a position where the target 27 is irradiated, as described later and as illustrated in FIG. 23. The drive laser controller 54 may control each of the first pulsed laser unit 3p1, the second pre-pulsed laser unit 3p2, the main pulsed laser unit 3M, and the beam adjusters 171, 172, and 173 on the basis of the data of the beam parameter mentioned above.

### (5.2 Operation)

FIG. 20 is a timing chart illustrating an example of control timings by the EUV light generation controller 5. Note that in (A) to (F) of FIG. 20, a vertical axis may indicate a signal level. In (G) to (I), (K), and (L) of FIG. 20, a vertical axis may indicate intensity of light. In (J) of FIG. 20, a vertical axis may indicate density or temperature of the plasma 2a.

The timing chart in FIG. 20 is different from the timing chart in FIG. 11 in that an output timing of a light emission trigger of the drive laser unit 3D is controlled on the basis of a passage timing signal Tm1 from the target detector 40 in place of the target output signal S1 in (A) of FIG. 11. Other control timings may be substantially similar to those in FIG. 11.

In the target detector 40, the target 27 may be illuminated with illumination light from the light source section 45. The target sensor 4 may receive the illumination light outputted from the light source section 45. Part of the illumination light may be blocked when the target 27 passes through the predetermined position P1 in the chamber 2 to thereby reduce light intensity to be received by the target sensor 4. The optical sensor 41 of the target sensor 4 may detect such change of light intensity, and the detected change may serve as a detection signal of the target The optical sensor 41 may output the detection signal as the passage timing signal Tm1. The target sensor 4 may output one pulse signal as the passage timing signal Tm1 every time one target 27 is detected. The passage timing signal Tm1 may be inputted to the EUV light generation controller 5.

The EUV light generation controller 5 may output the delay data Dt0 to the delay circuit 53 on the basis of the passage timing signal Tm1. The delay data Dt0 may indicate a delay time of each of various signals. The EUV light generation controller 5 may also output the trigger signal TG0 to the delay circuit 53 on the basis of the passage timing signal Tm1 so as to allow each of the various signals to be generated at a predetermined delay time. The various signals may include the probe pulse emission trigger TG2, the first pre-pulse emission trigger TGp1, the second pre-pulse emission trigger TGp2, the main pulse emission trigger TG1, and the shutter signal S2.

In the EUV light generating system, the drive pulsed laser light beam 31D and the probe pulsed laser light beam 31P may substantially coaxially enter the inside of the chamber 2. When the probe pulse emission trigger TG2 is inputted to the probe laser unit 30, the probe pulsed laser light beam 31P may be outputted, and the plasma 25a may he irradiated with the probe pulsed laser light beam 31P, as illustrated in (K) of FIG. 20. The Thomson scattered light 31T of the probe pulsed laser light beam 31P from the plasma 25a may enter entrance slit 151 of the spectrum measurement unit 140 via the fiber input optical system 153, the optical fiber 154, and the fiber output optical system 155. The spectrum measurement unit 140 may measure the spectrum of the ionic term in the Thomson scattered light 31T in synchronization with a pulse of the shutter signal S2 by the ICCD camera 135.

The EUV light generation controller 5 may perform control for setting of the condition parameter for exposure as described below, on the basis of the detection value derived from the energy sensor 52 and on the plasma parameter calculated from the spectrum waveform of the ionic term in the Thomson scattered light 31T.

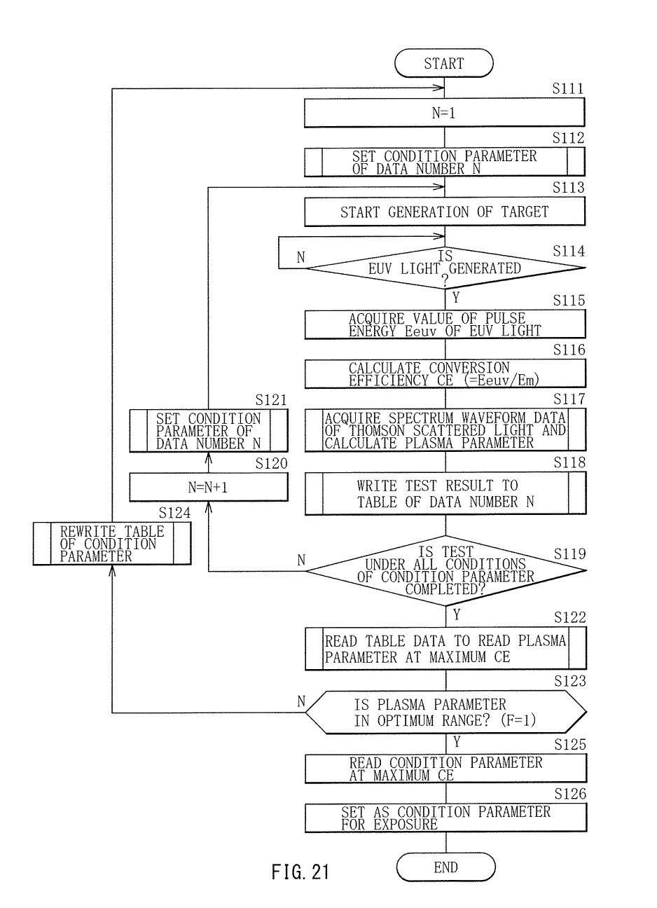

FIG. 21 is a main flow chart schematically illustrating an example of a flow of control for setting of the condition parameter for exposure with use of the Thomson scattering measurement system in the EUV light generating system illustrated in FIG. 18.

First, the EUV light generation controller 5 may set a value of a data number N to N=1 (step S111). Thereafter, the EUV light generation controller 5 may set a condition parameter of the data number N=1 as an initial parameter (step S112).

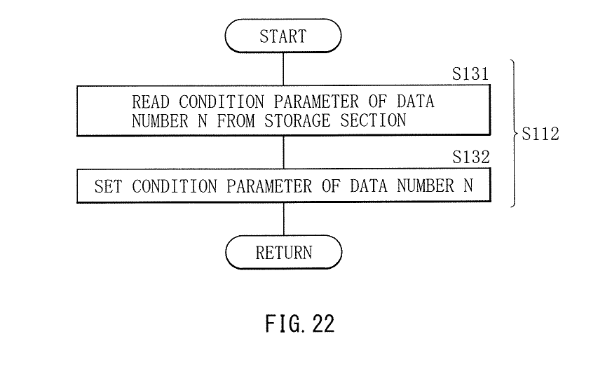

FIG. 22 is a sub-flow chart illustrating details of a process in the step S112. The EUV light generation controller 5 may read the condition parameter of the data number N=1 from the storage section 51 (step S131). Subsequently, the EUV light generation controller 5 may set the thus-read condition parameter of the data number N=1. as the initial parameter (step S132), and thereafter, the EUV light generation controller 5 may return to a main flow in FIG. 21.

FIG. 23 schematically illustrates an example of the initial condition parameter. The EUV light generation controller 5 may store data of the condition parameter of each data number in a table as illustrated in FIG. 23 in the storage section 51. The number of the data numbers equal to the number of necessary test conditions may be stored in the table. The condition parameter may include the beam parameter of each of the first pre-pulsed laser light beam 31p1, the second pre-pulsed laser light beam 31p2, and the main pulsed laser light beam 31M.

The beam parameter of the first pre-pulsed laser light beam 31p1 may include data of pulse energy Ep1, a pulse width ΔTp1, and a beam diameter Dp1. The beam parameter of the second pre-pulsed laser light beam 31p2 may include data of pulse energy Ep2, a pulse width ΔTp2, a beam diameter Dp2, and a delay time ΔT1-2 with respect to the first pre-pulsed laser light beam 31p1. The beam parameter of the main pulsed laser light beam 31M may include data of pulse energy Em, a pulse width ΔTm, a beam diameter Dm, and a delay time ΔT1-3 with respect to the first pre-pulsed laser light beam 31p1.

The condition parameter may further include a parameter of the target 27. The parameter of the target 27 may include data of a target diameter Dd1.

Next, the EUV light generation controller 5 may return to the main flow in FIG. 21, and may output the target output signal S1 to the target feeding unit 70 so as to cause the target feeding unit 70 to start generation of the target 27 (step S113). Subsequently, the EUV light generation controller 5 may determine whether the EUV light 251 is generated, on the basis of the detection value derived from the energy sensor 52 (step S114). When the EUV light generation controller 5 determines that the EUV light 251 is not generated (step S114; N), a process in the step S114 may be repeated.

When the EUV light generation controller 5 determines that the EUV light 251 is generated (step S114; Y), the EUV light generation controller 5 may then acquire a value of pulse energy Eeuv of the EUV light 251 on the basis of the detection value derived from the energy sensor 52 (step S115). Subsequently, the EUV light generation controller S may calculate conversion efficiency CE (=Eeuv/Em) from the pulse energy Eeuv and the pulse energy Em of the main pulsed laser light beam 31M (step S116).

Next, the EUV light generation controller 5 may acquire spectrum waveform data of the ionic term in the Thomson scattered light 31T and calculate the plasma parameter (step S117).

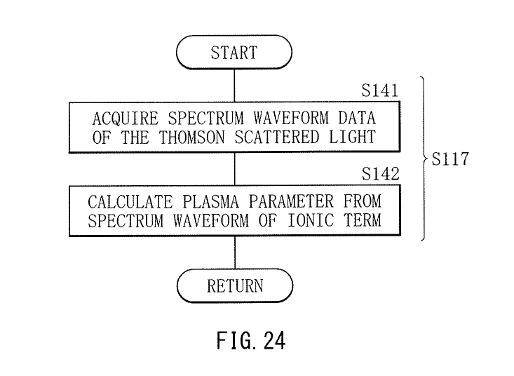

FIG. 24 is a sub-flow chart illustrating details of a process in the step S117. The EUV light generation controller 5 may acquire the spectrum waveform data of the ionic term in the Thomson scattered light 31T from image data of the ICCD camera 135 of the spectrum measurement unit 140 (step S141). Subsequently, the EUV light generation controller 5 may calculate the plasma parameter from the spectrum waveform of the ionic term (step S142), and may return to the main flow in FIG. 21. Calculation of the plasma parameter may be performed by calculation of a theoretical spectrum waveform that is substantially coincident with the spectrum waveform of the ionic term.

Next, the EUV light generation controller 5 may return to the main flow in FIG. 21, and may write data of a test result to a table of the data number N the storage section 51 (step S118).

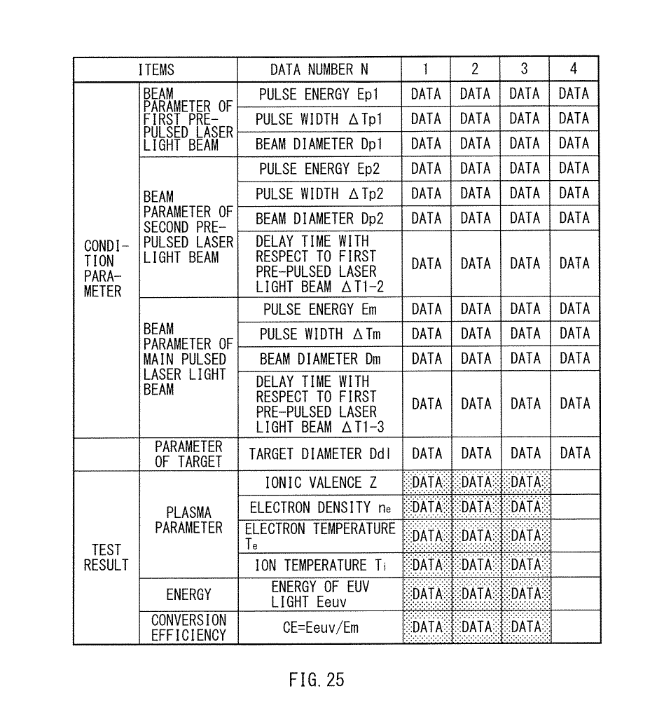

FIG. 25 schematically illustrates an example of data of the test result. The EUV light generation controller 5 may write the data of the test result in each data number to the table as illustrated in FIG. 25 in the storage section 51. Examples of the data of the test result may include the plasma parameter, the pulse energy Eeuv of the EUV light 251, and the conversion efficiency CE. The plasma parameter may include the ionic valence Z, the electron density nₑ, the electron temperature Tₑ, and the ion temperature Tᵢ.

Next, the EUV light generation controller 5 may determine whether a test for all data of the condition parameter stored in the storage section 51 is completed (step S119). When the EUV light generation controller 5 determines that the test for all data is not completed (step S119; N), the value of the data number N may be turned to N=N1 (step S120). Subsequently, the EUV light generation controller 5 may set the condition parameter of the data number N (step S121), and may return to a process in the step S113.

When the EUV light generation controller 5 determines that the test for all data is completed (step S119; Y), the EUV light generation controller 5 may read table data of the storage section 51 to read the plasma parameter at maximum conversion efficiency CE where the conversion efficiency CE is at maximum (step S122).

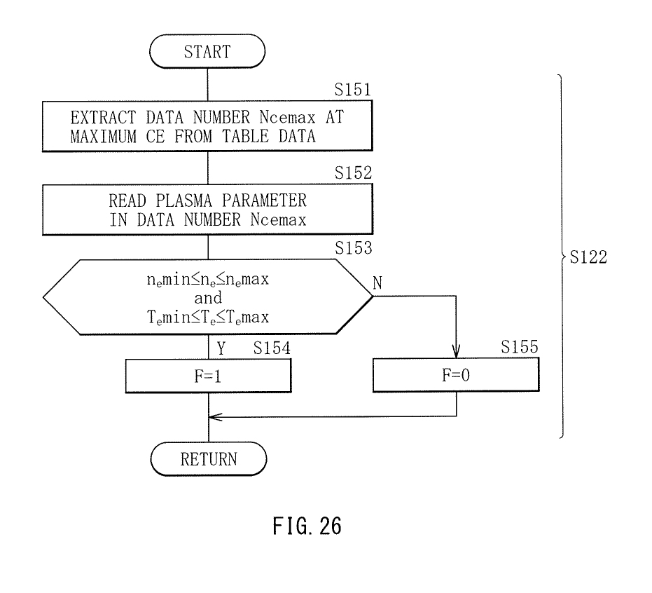

FIG. 26 is a sub-flow chart illustrating details of a process in the step S122. The EUV light generation controller 5 may extract, from the table data, a data number Ncemax at the maximum conversion efficiency CE where the conversion efficiency CE is at maximum (step S151). Subsequently, the EUV light generation controller 5 may read the plasma parameter in the data number Ncemax from the table data of the storage section 51 (step S152).

Next, the EUV light generation controller 5 may determine whether the electron density nₑ and the electron temperature Tₑ each fall in an acceptable range. In other words, the EUV light generation controller 5 may determine whether the electron density nₑ and the electron temperature Tₑ fall in a range of nₑmin≦nₑ≦nₑmax and a range of Tₑmin≦Tₑ≦Tₑmax, respectively (step S153). When the EUV light generation controller 5 determines that the electron density nₑ and the electron temperature Tₑ each fall in the acceptable range (step S153; Y), the EUV light generation controller 5 set a parameter value F to F=1 (step S154), and may return to the main flow in FIG. 21. When the EUV light generation controller 5 determines that the electron density nₑ and the electron temperature Tₑ each are out of the acceptable range (step S153; N), the EUV light generation controller 5 may set the parameter value F to F=0 (step S155), and may return to the main flow in FIG. 21. At this occasion, the parameter value F may indicate whether the plasma parameter falls in an optimum range.

Next, the EUV light generation controller 5 may return to the main flow in FIG. 21, and may determine whether the plasma parameter falls in an optimum range on the basis of the foregoing parameter value F (step S123). When the EUV light generation controller 5 determines that the plasma parameter is out of the optimum range (F=0, step S123; N), the EUV light generation controller 5 may rewrite the table of the condition parameter (step S124), and may return to a process in the step S111.

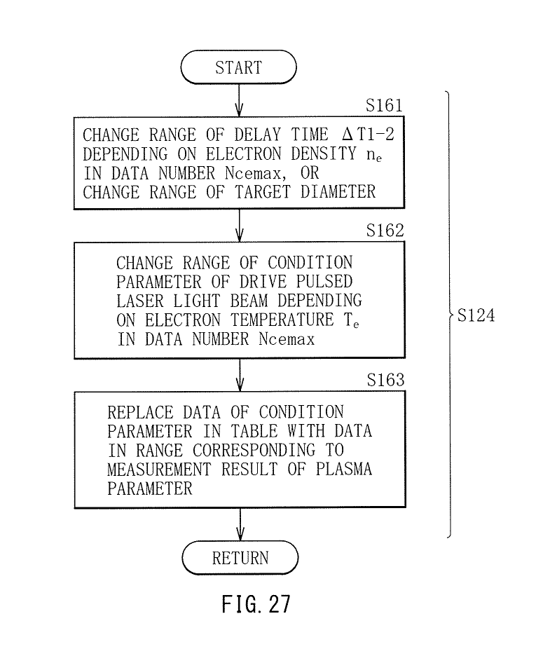

FIG. 27 is a sub-flow chart illustrating details of a process in the step S124. The EUV light generation controller 5 may change a range of the delay time ΔT1-2 depending on the electron density nₑ in the data number Ncemax. Alternatively, the EUV light generation controller 5 may change a range of the target diameter (step S161). For example, in a case in which the electron density nₑ when the conversion efficiency CE is at maximum is lower than desired density, the EUV light generation controller 5 may change the range of the delay time so as to decrease the delay times (ΔT1-2 and ΔT1-3). Moreover, in a case in which the electron density nₑ is higher than the desired density, the EUV light generation controller 5 may change the range of the delay time so as to increase the delay times (ΔT1- 2 and ΔT1-3). Alternatively, the EUV light generation controller 5 may change the range of the target diameter so as to decrease the target diameter in the case in which the electron density nₑ is higher than the desired density, and to increase the target diameter in the case in which the electron density nₑ is lower than the desired density.

Next, the EUV light generation controller 5 may change the range of the condition parameter of the drive pulsed laser light beam 31D depending on the electron temperature Tₑ in the data number Ncemax (step S162). For example, the EUV light generation controller 5 may change the range of the condition parameter so as to increase the pulse energy of the main pulsed laser light beam 31M in a case in which the electron temperature Tₑ when the conversion efficiency CE is at maximum is lower than a desired temperature. Moreover, the EUV light generation controller 5 may change the range of the condition parameter so as to decrease the pulse energy of the main pulsed laser light beam 31M in a case in which the electron temperature Tₑ when the conversion efficiency CE is at maximum is higher than the desired temperature,

Next, the EUV light generation controller 5 may replace the data of the condition parameter in the table in the storage section 51 with data in a range corresponding to a measurement result of the plasma parameter (step S163), and may return to the main flow in FIG. 21.

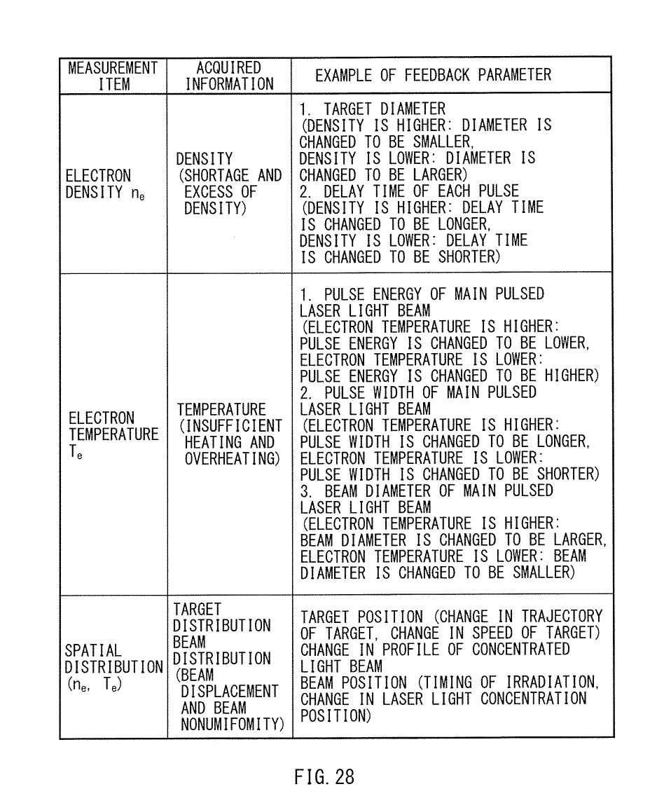

FIG. 28 schematically illustrates an example of rewritten contents of the condition parameter. Measurement items may include the electron density nₑ, the electron temperature Tₑ, and a spatial distribution (nₑ, Tₑ).

Information acquired from the measurement item of the electron density nₑ may include information of density, for example, information of shortage and excess of density. Information acquired from the measurement item of the electron temperature Tₑ may include information of temperature, for example, information of insufficient heating and overheating. Information acquired from the measurement item of the spatial distribution (nₑ, Tₑ) may include information of a target distribution and a beam distribution, for example, information of beam displacement and beam nonumifomity.

A feedback parameter of the electron density nₑ may include information of the target diameter and the delay times ΔT1-2 and ΔT1-3. Moreover, a feedback parameter of the electron temperature Tₑ may include information of the pulse energy, the pulse width, and the beam diameter of the main pulsed laser light beam 31M.

A feedback parameter of the spatial distribution (nₑ, Tₑ) may include a target position, change in profile of a concentrated light beam, and a beam position. Examples of the target position may include information of change in the trajectory of the target 27 and change in speed of the target 27. Examples of the beam position may include information of a timing of irradiation and change in a laser light concentration position.

Description returns to the main flow in FIG. 21. When the EUV light generation controller 5 determines that the plasma parameter falls in the optimum range (F=1, step S123; Y), the EUV light generation controller 5 may read, from the table data of the storage section 51, the condition parameter at the maximum conversion efficiency CE where the conversion efficiency CE is at maximum (step S125). Next, the EUV light generation controller 5 may set the condition parameter at the maximum conversion efficiency CE as the condition parameter for exposure (step S126), and may end the process.

### (5.3 Workings)

According to the second embodiment, each of the first pre-pulse emission trigger TGp1, the second pre-pulse emission trigger TGp2, and the main pulse emission trigger TGm1 may be delayed on the basis of the passage timing signal Tm1 of the target 27. This makes it possible to control timings of irradiation of the target 27 with the first pre-pulsed laser light beam 31p1, the second pre-pulsed laser light beam 31p2, and the main pulsed laser light beam 31M with high accuracy.

Moreover, measurement may be possible even in the target feeding unit 70 outputting the target 27 that is not on demand. To give a specific example, even the target feeding unit 70 of a continuous jet method may be applicable. In the continuous jet method, the target 27 in the droplet form may be generated by vibrating the nozzle 62 by a piezoelectric device

Further, the optical path axis of the probe pulsed laser light beam 31P is substantially coincident with the optical path axis of the drive pulsed laser light beam 31D, which makes it possible to eliminate necessity for the window 35 where the probe pulsed laser light beam 31P enters in FIG. 6 and an optical system delivering the probe pulsed laser light beam 31P. Furthermore, even if the light concentration position of the laser concentrating optical system 22a is changed, a plasma irradiation position of the probe pulsed laser light beam 31P is changed accordingly. This makes it possible to almost eliminate necessity for adjustment of the optical axis of the probe pulsed laser light beam 31P.

Moreover, the Thomson scattered light 31T from the plasma 25a enters the spectrum measurement unit 140 via the optical fiber 154, which makes it possible to facilitate alignment. Further, it is possible to attach the spectrum measurement unit 140 via the optical fiber 154 only upon measurement of the Thomson scattered light 31T and perform measurement.

### (5.4 Modification Examples)

In the embodiment in FIG. 18, the Thomson scattered light 31T enters the spectrum measurement unit 140 via the optical fiber 154; however, the Thomson scattered light 31T may enter the spectrum measurement unit 140 without the optical fiber 154 in a manner substantially similar to that in the embodiment in FIG. 6.

The embodiment in FIG. 19 involves the first pre-pulsed laser unit 3p1, the second pre-pulsed laser unit 3p2, and the main pulsed laser unit 3M as the configuration of the drive laser unit 3D; however, the embodiment is not limited thereto. For example, the drive laser unit 3D may include the main pulsed laser unit 3M only. Alternatively, for example, the drive laser unit 3D may include the main pulsed laser unit 3M and the first pre-pulsed laser unit 3p1 only. Alternatively, for example, the drive laser unit 3D may include three or more pre-pulsed laser units 3P.

Moreover, in order to measure the spatial distribution of the plasma 25a, for example, the entrance sleeve of the fiber input optical system 153 may be fixed to an automatic stage, and the entrance sleeve may be moved by the automatic stage to measure the spectrum of the ionic term at respective positions. Further, in order to measure a distribution in a Z-axis direction at once, the optical fibers 154 may be bundled, and the optical fibers 154 may be disposed side by side along a vertical direction in an input sleeve and an output sleeve. A direction where the optical fibers 154 in the input sleeve are disposed side by side may be substantially coincident with the Z-axis direction. The fiber input optical system 153 and the fiber output optical system 155 may be disposed so as to allow a direction where the optical fibers 154 in the output sleeve are disposed side by side to be substantially coincident with the longitudinal direction of the entrance slit 151 of the spectrum measurement unit 140.

### 6. Other Embodiments

(6.1 Embodiment of Target Feeding Unit Allowing for Control of Target Diameter)

(6.1.1 Configuration)

FIG. 29 schematically illustrates an example of an embodiment of the target feeding unit 70 that allows for adjustment of the target diameter. The target feeding unit 70 may include the target feeder 26, a pressure adjuster 65, a piezoelectric power source 66, a function generator 67, and a target controller 71.

The target feeder 26 may include a tank 61, a heater 64, a nozzle 62, and a piezoelectric device 63. The tank 61 may store a target material 69 such as tin. The heater 64 may heat the target material 69. The nozzle 62 may include a nozzle hole 62a through which the target material 69 is outputted. The piezoelectric device 63 may vibrate the nozzle 62.

The pressure adjuster 65 may be coupled to the tank 61 by piping so as to control pressure from an inert gas source 68 to a predetermined pressure. The function generator 67 may supply the piezoelectric device 63, via the piezoelectric power source 66, with a voltage of a predetermined PM modulation function.

### (6.1.2 Operation)

The target controller 71 may perform temperature control to heat the target material 69 stored in the tank 61 to a predetermined temperature by the heater 64. For example, in a case in which the target material 69 is tin, the target controller 71 may perform temperature control to heat the target material 69 to, for example, a predetermined temperature of about 232° C., which is the melting point of tin, or higher, for example, to a predetermined temperature in a range from 250° C. to 290° C. both inclusive.

The target controller 71 may receive the data Dt2 of the target diameter serving as a desired target diameter from the EUV light generation controller 5. The target controller 71 may calculate a voltage waveform to be applied to the piezoelectric device 63. The voltage waveform may allow the target diameter to become the desired target diameter. A voltage to be applied to the piezoelectric device 63 may be, for example, a carrier wave fc and a PM modulation function of a modulated wave fm.

When the target controller 71 receives the target output signal S1 from the EUV light generation controller 5, the target controller 71 may control the pressure adjuster 65 so that the pressure becomes a pressure at which a jet that eventually serves as the target 27 is outputted at predetermined speed from the nozzle hole 62a of the nozzle 62. Thereafter, the target controller 71 may output a control signal to the function generator 67. The control signal may indicate a calculated PM modulation function. The function generator 67 may supply the piezoelectric device 63, via the piezoelectric power source 66, with the voltage of the PM modulation function. Thus, a liquid jet of the target material 69 may be outputted from the nozzle hole 62a of the nozzle 62. Vibration may be transferred to the liquid jet by the piezoelectric device 63, and a plurality of targets 27 in the droplet form may be generated by the carrier wave fc of the PM modulation. Thereafter, the plurality of targets 27 in the droplet form may be combined into one target 27 by the modulated wave fm.

In such a target feeding unit 70 changing the modulated wave fm makes it possible to change the number of combinations of the targets 27 in the droplet form, thereby controlling the target diameter.

### (6.2 Embodiment of Laser Unit Allowing for Control of Pulse Width)

FIG. 30 schematically illustrates an example of an embodiment of a laser unit that allows for control of a pulse width and pulse energy. In the following, description is given of an embodiment that allows for control of the pulse width and the pulse energy of the drive pulsed laser light beam 31D outputted from the drive laser unit 3D.

### (6.2.1 Configuration)

The drive laser unit 3D may include a master oscillator (MO) 110 including a Q switch, an optical shutter 120, and an amplifier PA1.

The master oscillator 110 may include a CO₂ laser discharge tube 113, an acousto-optical device 114, an optical resonator, a high-frequency power source 115, and an acousto-optical device driver 116. The CO₂ laser discharge tube 113 may contain a CO₂ laser gas, and may include a pair of electrodes 117a and 117b and two windows 118 and 119. The pair of electrodes 117a and 117b may be coupled to the high-frequency power source 115. The optical resonator may include a high reflection mirror 111 and a partial reflection mirror 112, and the CO₂ laser discharge tube 113 and the acousto-optical device 114 may be disposed in an optical path of the optical resonator.

The optical shutter 120 may include a Pockels cell 121, a polarizer 122, and a Pockels cell driver 123. The Pockels cell 121 and the polarizer 122 may be disposed in an optical path of pulsed laser light outputted from the master oscillator 110

The amplifier PA1 may include a CO₂ laser discharge tube 124 and a high-frequency power source 125. The CO₂ laser discharge tube 124 may be disposed in an optical path of pulsed laser light having passed through the optical shutter 120. The CO₂ laser discharge tube 124 may contain a CO₂ laser gas, and may include a pair of electrodes 126a and 126b and two windows 127 and 128. The pair of electrodes 126a and 126b may be coupled to the high-frequency power source 125.

### (6.2.2 Operation)

The EUV light generation controller 5 may output the data Dt1 of desired pulse energy and a desired pulse width to the drive laser controller 54. In order to achieve the desired pulse energy, the drive laser controller 54 may apply a voltage to the pair of electrodes 117a and 117b of the master oscillator 110 via the high-frequency power source 115 to cause electric discharge between the pair of electrodes 117a and 117b, resulting in excitation.

In order to achieve he desired pulse energy, the drive laser controller 54 may apply a voltage to the pair of electrodes 126a and 126b of the amplifier PA1 via the high-frequency power source 125 to cause electric discharge between the pair of electrodes 126a and 126b, resulting in excitation.

When the drive laser controller 54 receives the drive pulse emission trigger TG1 from the delay circuit 53, the drive laser controller 54 may control the acousto-optical device 114 via the acousto-optical device driver 116 so as to serve as a Q switch. Accordingly, pulsed laser light with about several hundreds of ns may be outputted from the partial reflection mirror 112.

Moreover, the drive laser controller 54 may control an opening time of the optical shutter 120 via the Pockets cell driver 123 so as to allow the pulsed laser light with about several hundreds of ns to have the desired pulse width. The pulsed laser light having passed through the optical shutter 120 may have, for example, a single pulse of a several tens of ns that is close to the desired pulse width. The pulsed laser light that is single-pulsed may be amplified when passing through the amplifier PA1. The pulsed laser light amplified by the amplifier PA1 may have characteristics close to the desired pulse energy and the desired pulse width.

Note that the number of the amplifiers PA1 is not limited to one, and a plurality of amplifiers may be provided. Moreover, a monitor that measures the pulse energy and the pulse waveform may be provided to the drive laser unit 3D, and may perform feedback control to adjust the pulse energy and the pulse width to the desired pulse energy and the desired pulse width, respectively.

(6.3 Embodiment of Thomson Scattering Measurement System where Probe Pulsed Laser Light Beam Enters Perpendicularly to Drive pulsed Laser Light Beam)

FIG. 31 schematically illustrates a modification example of a direction where the probe pulsed laser light beam 31P enters. For example, the plasma 25a may be irradiated with the probe pulsed laser light beam 31P from an axis including an XY plane that includes the plasma generation region 25, as illustrated in FIG. 31.

### (6.4 Embodiment of ICCD)

FIG. 32 schematically illustrates a configuration example of an ICCD.

The ICCD camera 135 may include an ICCD (an intensified CCD or an image intensifier CCD), as illustrated in FIG. 32. The ICCD may include an image intensifier 180 and a CCD 190. The image intensifier 180 may include an entrance window 181, a photoelectric surface 182, a microchannel plate (MCP) 183, a fluorescent screen 184, and a fiber-optic plate 185 in the order thereof from the entrance side of the light.

The MCP 183 may include a large number of thin channels, each of which may form an electron multiplier. The fiber-optic plate 185 may have a configuration in which a large number of optical fibers are bundled. The CCD 190 may be disposed on light exit surface side of the fiber-optic plate 185.

FIG. 33 schematically illustrates an example of operation of the image intensifier 180.

in the image intensifier 180, light 191 having entered the entrance window 181 may he converted into electrons 192 by the photoelectric surface 182. A plurality of electrons 192 corresponding to a light amount of the light 191 may be outputted from the photoelectric surface 182. The respective electrons 192 outputted from the photoelectric surface 182 may be accelerated in accordance with a potential between the photoelectric surface 182 and an entrance surface of the MCP 183 to enter the respective channels of the MCP 183. The MCP 183 may output intensified electrons 193 to the fluorescent screen 184. The fluorescent screen 184 may output light corresponding to the amount of the electrons 193 having entered the fluorescent screen 184. The fiber-optic plate 185 may transmit the light outputted from the fluorescent screen 184 as amplified light 194 to the exit surface side. At this occasion, controlling a potential difference between the photoelectric surface 182 and the entrance surface of the MCP 183 may enable a shutter function of the image intensifier 180.

Through the foregoing principle, the image intensifier 180 may amplify luminance of an optical image while keeping position information of the optical image having entered the image intensifier 180. Note that a transfer lens may be provided in place of the fiber-optic plate 185. The transfer lens may transfer, onto an imaging device of the CCD 190, the optical image formed on the fluorescent screen 184.

### 7. Hardware Environment of Controller

A person skilled in the art will appreciate that a general-purpose computer or a programmable controller may be combined with a program module or a software application to execute any subject matter disclosed herein. The program module, in general, may include one or more of a routine, a program, a component, a data structure, and so forth that each causes any process described in any example embodiment of the present disclosure to be executed.

FIG. 34 is a block diagram illustrating an exemplary hardware environment in which various aspects of any subject matter disclosed therein may be executed. An exemplary hardware environment 100 in FIG. 34 may include a processing unit 1000, a storage unit 1005, a user interface 1010, a parallel input/output (I/O) controller 1020, a serial I/O controller 1030, and an analog-to-digital (A/D) and digital-to-analog (D/A) converter 1040. Note that the configuration of the hardware environment 100 is not limited thereto.

The processing unit 1000 may include a central processing unit (CPU) 1001, a memory 1002, a timer 1003, and a graphics processing unit (GPU) 1004. The memory 1002 may include a random access memory (RAM) and a read only memory (ROM). The CPU 1001 may be any commercially-available processor. A dual microprocessor or any other multi-processor architecture may be used as the CPU 1001.

The components illustrated in FIG. 34 may be coupled to one another to execute any process described in any example embodiment of the present disclosure.

Upon operation, the processing unit 1000 may load programs stored in the storage unit 1005 to execute the loaded programs. The processing unit 1000 may read data from the storage unit 1005 together with the programs, and may write data in the storage unit 1005. The CPU 1001 may execute the programs loaded from the storage unit 1005. The memory 1002 may be a work area in which programs to be executed by the CPU 1001 and data to be used for operation of the CPU 1001 are held temporarily. The timer 1003 may measure time intervals to output a result of the measurement to the CPU 1001 in accordance with the execution of the programs. The GPU 1004 may process image data in accordance with the programs loaded from the storage unit 1005, and may output the processed image data to the CPU 1001.

The parallel I/O controller 1020 may be coupled to parallel I/O devices operable to perform communication with the processing unit 1000, and may control the communication performed between the processing unit 1000 and the parallel I/O devices. Non-limiting examples of the parallel I/O devices may include the delay circuit 53, the target feeding unit 70, and the ICCD camera 135. The serial I/O controller 1030 may be coupled to a plurality of serial I/O devices operable to perform communication with the processing unit 1000, and may control the communication performed between the processing unit 1000 and the serial I/O devices. Non-limiting examples of serial I/O devices may include the drive laser unit 3D, the main pulsed laser unit 3M, the pre-pulsed laser unit 3P, the first pre-pulsed laser unit 3p1, and the second pulsed laser unit 3p2. The A/D and D/A converter 1040 may be coupled to analog devices such as various kinds of sensors through respective analog ports. Non-limiting examples of the sensors may include the energy sensor 52. The A/D and D/A converter 1040 may control communication performed between the processing unit 1000 and the analog devices, and may perform analog-to-digital conversion and digital-to-analog conversion of contents of the communication.

The user interface 1010 may provide an operator with display showing a progress of the execution of the programs executed by the processing unit 1000, such that the operator is able to instruct the processing unit 100 to stop execution of the programs or to execute an interruption routine.

The exemplary hardware environment 100 may be applied to one or more of configurations of the EUV light generation controller 5 and other controllers according to any example embodiment of the present disclosure. A person skilled in the art will appreciate that such controllers may be executed in a distributed computing environment, namely, in an environment where tasks may be performed by processing units linked through any communication network. In any example embodiment of the present disclosure, controllers such as the EUV light generation controller 5 may be coupled to one another through a communication network such as Ethernet (Registered Trademark) or the Internet. In the distributed computing environment, the program module may be stored in each of local and remote memory storage devices.

### 8. Et Cetera

The foregoing description is intended to be merely illustrative rather than limiting. It should therefore be appreciated that variations may be made in example embodiments of the present disclosure by persons skilled in the art without departing from the scope as defined by the appended claims.

The terms used throughout the specification and the appended claims are to be construed as “open-ended” terms. For example, the term “include” and its grammatical variants are intended to be non-limiting, such that recitation of items in a list is not to the exclusion of other like items that can be substituted or added to the listed items. The term “have” and its grammatical variants are intended to be non-limiting, such that recitation of items in a list is not to the exclusion of other like items that can be substituted or added to the listed items. Also, the singular forms “a”, “an”, and “the” used in the specification and the appended claims include plural references unless expressly and unequivocally limited to one referent.

What is claimed is:

1. An extreme ultraviolet light generating system, comprising:
a chamber;
a target feeding unit configured to feed a target into the chamber;
a drive laser unit configured to irradiate the target with a drive pulsed laser light beam to generate a plasma to thereby generate extreme ultraviolet light;
a probe laser unit configured to irradiate the plasma with a probe pulsed laser light beam to thereby generate Thomson scattered light;
a spectrometer configured to measure a spectrum waveform of an ionic term in the Thomson scattered light; and
a wavelength filter disposed upstream of the spectrometer, and configured to suppress light with a predetermined wavelength from entering the spectrometer, the light with the predetermined wavelength being part of light containing the Thomson scattered light, and the predetermined wavelength being substantially same as a wavelength of the probe pulsed laser light beam.

2. The extreme ultraviolet light generating system according to claim 1, further comprising an energy sensor configured to detect energy of the extreme ultraviolet light.

3. The extreme ultraviolet light generating system according to claim 2, further comprising a controller configured to calculate a plasma parameter from the spectrum waveform of the ionic term in the Thomson scattered light, and control the drive laser unit to allow a characteristic of the drive pulsed laser light beam to be optimized on a basis of a detection value derived from the energy sensor and the plasma parameter, the plasma parameter indicating a characteristic of the plasma.

4. The extreme ultraviolet light generating system according to claim 3, wherein the characteristic of the drive pulsed laser light beam includes one or more of pulse energy of the drive pulsed laser light beam, a pulse width of the drive pulsed laser light beam, a beam diameter of the drive pulsed laser light beam, and a timing of irradiation of the target with the drive pulsed laser light beam.

5. The extreme ultraviolet light generating system according to claim 3, wherein
the drive pulsed laser light beam includes a pre-pulsed laser light beam and a main pulsed laser light beam, the pre-pulsed laser light beam diffusing the target, and the main pulsed laser light beam turning the diffused target into the plasma,
the drive laser unit includes a pre-pulsed laser unit and a main pulsed laser unit, the pre-pulsed laser unit being configured to output the pre-pulsed laser light beam, and the main pulsed laser unit being configured to output the main pulsed laser light beam, and
the controller controls one or both of the pre-pulsed laser unit and the main pulsed laser unit to allow one or both of a characteristic of the pre-pulsed laser light beam and a characteristic of the main pulsed laser light beam to be optimized on the basis of the detection value derived from the energy sensor and on the plasma parameter.

6. The extreme ultraviolet light generating system according to claim 2, further comprising a controller configured to calculate a plasma parameter from the spectrum waveform of the ionic term in the Thomson scattered light, and control the target feeding unit to allow a diameter of the target to be optimized on a basis of a detection value derived from the energy sensor and on the plasma parameter, the plasma parameter indicating a characteristic of the plasma.

7. The extreme ultraviolet light generating system according to claim 1, wherein the following relationship is satisfied:
Δλs/Δλp≦50/60
where Δλs a wavelength width of light suppressed by the wavelength filter, and Δλp is a difference between two peak wavelengths each measured as the ionic term in the Thomson scattered light.

8. The extreme ultraviolet light generating system according to claim 7, wherein the following relationship is satisfied:
Δλs/Δλp≦50/60
where Δλf is a full width at half maximum of a device function of the spectrometer.

9. The extreme ultraviolet light generating system according to claim 1, wherein the target contains one of tin, gadolinium, and terbium.

10. The extreme ultraviolet light generating system according to claim 1, wherein the wavelength filter includes:
a dispersion optical system configured to spatially disperse the light containing the Thomson scattered light depending on a wavelength of that light; and
a blocking member configured to block the light with the predetermined wavelength in dispersed light derived from the dispersion optical system.

11. The extreme ultraviolet light generating system according to claim 10, wherein the wavelength filter further includes an inverse dispersion optical system configured to perform inverse dispersion of the dispersed light, having been subjected to the blocking of the light with the predetermined wavelength by the blocking member, spatially depending on a wavelength of that dispersed light.

12. The ex treme ultraviolet light generating system according to claim 10, wherein the dispersion optical system includes a dispersion grating configured to diffract the light containing the Thomson scattered light depending on the wavelength of that light.

13. The extreme ultraviolet light generating system according to claim 11, wherein the inverse dispersion optical system includes an inverse dispersion grating configured to diffract the dispersed light, having been subjected to the blocking of the light with the predetermined wavelength by the blocking member, depending on the wavelength of that dispersed light.

14. An extreme ultraviolet light generating method, comprising:
feeding a target into a chamber;
irradiating the target with a drive pulsed laser light beam to generate plasma to thereby generate extreme ultraviolet light;
irradiating the plasma with a probe pulsed laser light beam to thereby generate Thomson scattered light;
measuring, by a spectrometer, a spectrum waveform of an ionic term in the Thomson scattered light; and
suppressing, upstream of the spectrometer, light with a predetermined wavelength from entering the spectrometer, the light with the predetermined wavelength being part of light containing the Thomson scattered light, and the predetermined wavelength being substantially same as a wavelength of the probe pulsed laser light beam.

15. A Thomson scattering measurement system, comprising:
a probe laser unit configured to irradiate a plasma with a probe pulsed laser light beam to thereby generate Thomson scattered light;
a spectrometer configured to measure a spectrum waveform of an ionic term in the Thomson scattered light; and
a wavelength filter disposed upstream of the spectrometer, and configured to suppress light with a predetermined wavelength from entering the spectrometer, the light with the predetermined wavelength being part of light containing the Thomson scattered light, and the predetermined wavelength being substantially same as a wavelength of the probe pulsed laser light beam.

16. The Thomson scattering measurement system according to claim 15, wherein the plasma is generated by irradiation of a target with a drive pulsed laser light beam.
